(19) United States
(12) Patent Application Publication
(10) Pub. No.: US 2026/0339213 A1
(43) Pub. Date: Oct. 29, 2026

(54) METHOD OF MANUFACTURING SEMICONDUCTOR DEVICES, AND RESIST UNDERLAYER COMPOSITIONS

(71) Applicant: Taiwan Semiconductor Manufacturing Company, Ltd., Hsinchu (TW)

(72) Inventors: Yen-Yu KUO, Hsinchu (TW); Yahru CHENG, Hsinchu (TW)

(73) Assignee: Taiwan Semiconductor Manufacturing Company, Ltd., Hsinchu (TW)

(21) Appl. No.: 19/183,530

(22) Filed: Apr. 18, 2025

(51) Int. Cl. G03F 7/11; G03F 7/004; G03F 7/38; H01L 21/027

(52) U.S. Cl. CPC G03F 7/11; G03F 7/0042; G03F 7/38; H10P 76/2041

(57) ABSTRACT

A method for manufacturing a semiconductor device includes forming a resist underlayer over a substrate. The resist underlayer includes an underlayer composition including a polymer including photoacid generator (PAG) groups. The PAG groups include cationic moieties ionically bonded to anionic moieties. The cationic moieties are covalently bonded to the polymer. The method further includes forming a photoresist layer including a photoresist composition over the resist underlayer, selectively exposing the photoresist layer to actinic radiation, and developing the selectively exposed photoresist layer to form a pattern in the photoresist layer.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to an embodiment of the disclosure.

FIG. 2 shows a process stage of a sequential operation according to an embodiment of the disclosure.

FIGS. 3A and 3B show a process stage of a sequential operation according to embodiments of the disclosure.

FIG. 4 shows a process stage of a sequential operation according to an embodiment of the disclosure.

FIGS. 5A and 5B show process stages of sequential operations according to embodiments of the disclosure.

FIGS. 6A and 6B show process stages of sequential operations according to embodiments of the disclosure.

FIGS. 7A, 7B, 7C, 7D, and 7E show a sequence of process stages according to embodiments of the disclosure.

FIGS. 8A, 8B, 8C, 8D, and 8E show a sequence of process stages according to embodiments of the disclosure.

FIG. 9 illustrates a process flow of manufacturing a semiconductor device according to an embodiment of the disclosure.

FIG. 10 shows a process stage of a sequential operation according to an embodiment of the disclosure.

FIG. 11 illustrates a process flow of manufacturing a semiconductor device according to an embodiment of the disclosure.

FIG. 12 shows a process stage of a sequential operation according to an embodiment of the disclosure.

FIGS. 13A, 13B, and 13C illustrate polymers containing photoacid generators and/or thermal acid generators according to embodiments of the disclosure.

FIG. 14A schematically illustrates a photoacid generator group bonded to a polymer, with a cationic moiety of the photoacid generator group covalently bonded to the polymer, according to embodiments of the disclosure. FIG. 14B schematically illustrates the photoacid generator group in FIG. 14A upon irradiation of the photoacid generator group such that an anionic moiety disassociates from the cationic moiety, according to embodiments of the disclosure.

FIGS. 15A, 15B, 15C, 15D, 15E, and 15F illustrate examples of cationic moieties of photoacid generators according to embodiments of the present disclosure.

FIGS. 16A, 16B, 16C, 16D, 16E, 16F, 16G, 16H, 16I, 16J, 16K, 16L, and 16M illustrate examples of anionic moieties of photoacid generators according to embodiments of the present disclosure.

FIGS. 17A, 17B, 17C, 17D, 17E, 17F, 17G, 17H, and 17I illustrate examples thermal acid generators according to embodiments of the present disclosure.

FIG. 18 illustrates an effect of a photoacid generator in a resist underlayer according to embodiments of the disclosure.

FIG. 19A illustrates a polymer with a pendant crosslinking group according to embodiments of the disclosure. FIGS. 19B, 19C, 19D, 19E, 19F, 19G, 19H, and 19I illustrate crosslinking groups according to embodiments of the disclosure.

FIG. 20 shows a process stage of a sequential operation according to embodiments of the disclosure.

FIG. 21A shows organometallic precursors according to embodiments of the disclosure.

FIG. 21B shows a reaction the organometallic precursors undergo when exposed to actinic radiation. FIG. 21C shows examples of organometallic precursors according to embodiments of the disclosure.

FIG. 22 illustrates a deposition apparatus according to embodiments of the disclosure.

FIG. 23 shows a process stage of a sequential operation according to embodiments of the disclosure.

FIGS. 24A and 24B show process stages of sequential operations according to embodiments of the disclosure.

FIG. 25 shows a process stage of a sequential operation according to embodiments of the disclosure.

FIGS. 26A and 26B show process stages of sequential operations according to embodiments of the disclosure.

FIGS. 27A and 27B show process stages of sequential operations according to embodiments of the disclosure.

FIG. 28 shows a process stage of a sequential operation according to embodiments of the disclosure.

FIG. 29 shows a process stage of a sequential operation according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper,” “top,” “bottom,” “middle,” and the like, may be used herein for ease of description to describe one element or feature's relationship to another element(s) or feature(s) as illustrated in the figures, and do not preclude additional structures above or below or between the stated feature. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C (A, B, C, A and B, A and C, B and C, or A, B and C), and does not mean one element from A, one element from B and one element from C, unless otherwise described. In the following embodiments, materials, configurations, dimensions, processes and/or operations as described with respect to one embodiment (e.g., one or more figures) may be employed in the other embodiments, and detailed description thereof may be omitted.

Extreme ultraviolet (EUV) lithography to achieve sub-20 nm half-pitch resolution is under development for mass production for next generation sub 5 nm node. EUV lithography requires a high-performance photoresist with high sensitivity for cost reduction of the high-power exposure source, and to provide good image resolution.

However, in a positive tone developing process, the concentration of acid, which is generated by a photoacid generator in a photoresist layer may be insufficient at the bottom of the photoresist layer. The low amount of acid may decrease photoresist polymer solubility in a developer, such as a tetramethyl ammonium hydroxide (TMAH) solution, thereby producing one or more of scum or collapse of the structure of a patterned photoresist. In addition, the low acid concentration may cause undercut structures at a bottom region of patterned photoresist layer proximal to an underlying layer. In a negative tone developing process, the acid generated by the photoacid generator at the exposure area may diffuse to the non-exposure area to cause low polymer solubility in the developer, such as an organic solvent, thereby producing scum. A dry descum process may be performed to remove the bottom scum. However, the non-selective descum process may also consume a portion of the desired photoresist pattern, and cause bridge defects after pattern transferring. Furthermore, metal-containing photoresists suffer from EUV light Z-factor decrease and are susceptible to forming the undercut structure.

Embodiments of this disclosure provide improved integrity of the photoresist pattern through reducing undercut structures, increasing thickness of bases of patterned structures proximal to an underlying layer, and reducing scum production upon development. Embodiments of this disclosure also serve to improve process windows of photolithographic processes

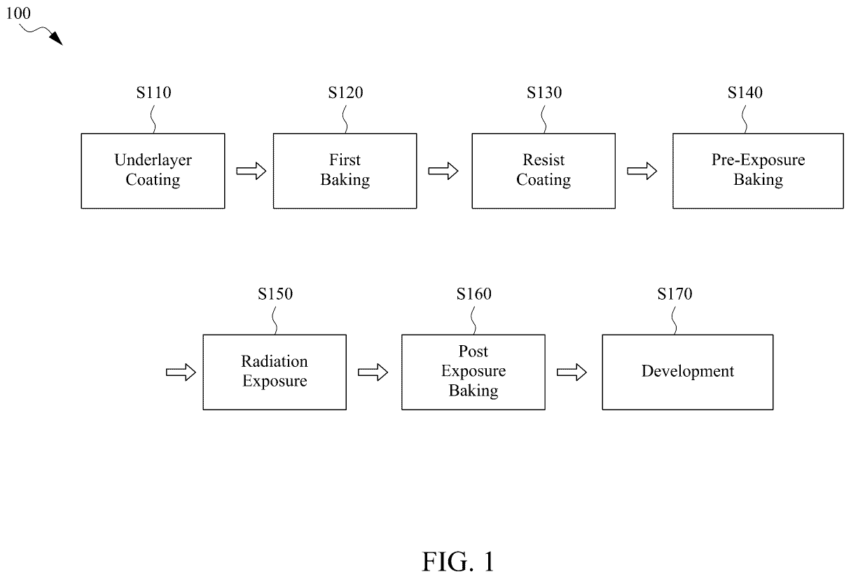

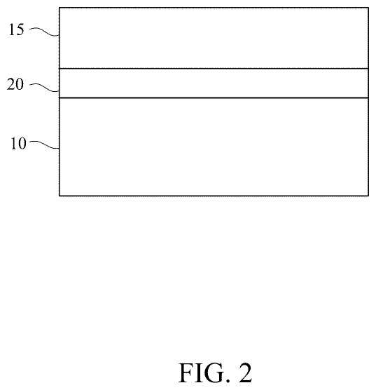

FIG. 1 illustrates a process flow 100 of manufacturing a semiconductor device according to embodiments of the disclosure. A resist underlayer composition is coated on a surface of a layer to be patterned (target layer) or a substrate 10 in operation S110, in some embodiments, to form a resist underlayer (or bottom layer) 20, as shown in FIG. 2. Then the resist underlayer 20 undergoes a first baking operation S120 to evaporate solvents in the underlayer composition in some embodiments. The resist underlayer 20 is baked at a temperature and time sufficient to cure and dry the resist underlayer 20. In some embodiments, the resist underlayer is heated at a temperature in a range of about 80° C. to about 400° C. for about 10 seconds to about 10 minutes. In some embodiments, the resist underlayer is heated at a temperature ranging from about 150° C. to about 250° C. Heating the resist underlayer at temperatures below the disclosed ranges may result in insufficient curing, while heating the underlayer at temperatures greater than the disclosed ranges may result in damage to the underlayer and the underlying device features.

A resist layer composition is subsequently coated on a surface of the resist underlayer 20 in operation S130, in some embodiments, to form a resist layer 15, as shown in FIG. 2. In some embodiments, the resist layer 15 is a photoresist layer. Then the photoresist layer 15 undergoes a second baking operation S140 (or pre-exposure baking operation) to evaporate solvents in the resist composition in some embodiments. The photoresist layer 15 is baked at a temperature and time sufficient to cure and dry the photoresist layer 15. In some embodiments, the photoresist layer is heated at a temperature of about 40° C. to about 150° C. for about 10 seconds to about 10 minutes. In some embodiments, the photoresist layer composition is coated on the resist underlayer 20 prior to baking the resist underlayer 20, and the photoresist layer 15 and resist underlayer 20 are baked together in a single baking operation to drive off solvents or cure both layers.

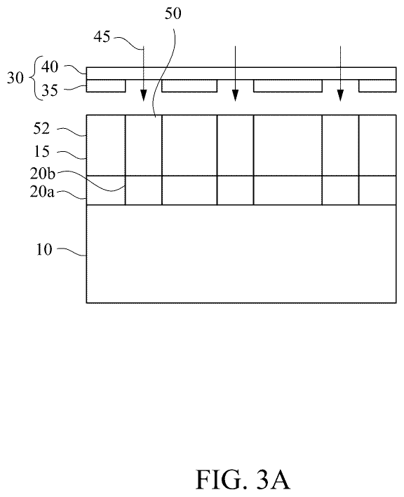

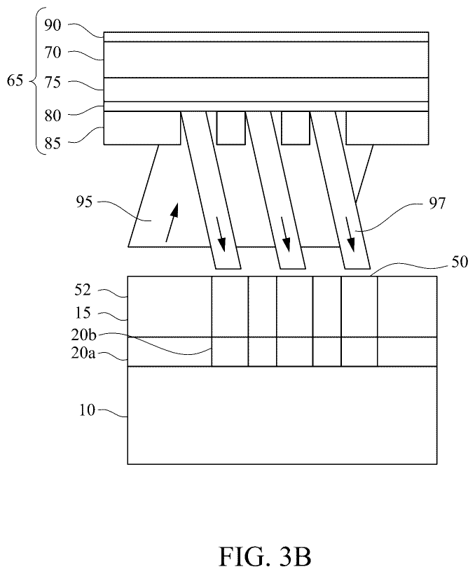

After the second (or pre-exposure) baking operation S140 of the photoresist layer 15, the photoresist layer 15 is selectively exposed to actinic radiation 45/97 (see FIGS. 3A and 3B) in operation S150. In some embodiments, the photoresist layer 15 is selectively exposed to ultraviolet radiation. In some embodiments, the radiation is electromagnetic radiation, such as g-line (436 nm wavelength), i-line (365 nm wavelength), ultraviolet radiation, deep ultraviolet radiation, and extreme ultraviolet radiation, and electron beams. In some embodiments, the radiation source is selected from the group consisting of a mercury vapor lamp, xenon lamp, carbon arc lamp, a KrF excimer laser light (248 nm wavelength), an ArF excimer laser light (193 nm wavelength), an F2 excimer laser light (157 nm wavelength), or a CO₂ laser-excited Sn plasma (extreme ultraviolet, 13.5 nm wavelength). The selective exposure to actinic radiation activates photoacid generator (PAG) groups in one or more of the resist underlayer and the photoresist layer so that the PAG groups generate an acid.

As shown in FIG. 3A, the exposure radiation 45 passes through a photomask 30 before irradiating the photoresist layer 15, in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In some embodiments of an extreme ultraviolet lithography operation, a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction. In addition to causing the chemical reaction in the photoresist layer 15, a portion of the radiation 45/97 also passes through the photoresist layer 15 and causes a reaction in the resist underlayer 20. The reaction in the resist underlayer 20 results in an acid being generated, which subsequently diffuses into the photoresist layer 15. FIGS. 3A and 3B show exposed portions 20b and non-exposed portions 20a of the resist underlayer 20.

Next, the photoresist layer 15 and the resist underlayer 20 undergo a third baking (or post-exposure bake (PEB)) in operation S160. In some embodiments, the photoresist layer 15 and the resist underlayer 20 are heated at a temperature of about 50° C. to about 450° C., about 80° C. to about 400° C., about 100° C. to about 350° C., for about 20 seconds to about 120 seconds. In some embodiments, the PEB temperature for activating crosslinking groups in the resist underlayer ranges from about greater than 100° C. to about less than 400° C. In some embodiments, the PEB temperature for aiding acid generation from photoacid groups in the resist underlayer after exposure ranges from about 80° C. to about 350° C. The post-exposure baking may be used to assist in the generating, dispersing, and reacting of the acid generated in the portions of the resist underlayer exposed to actinic radiation 45/97 during the exposure, and to assist in the diffusion of the acid generated in the exposed portion 20b of the resist underlayer into the photoresist layer 15. Such assistance helps to create or enhance chemical reactions, which generate chemical differences between the exposed region 50 and the unexposed region 52 within the photoresist layer.

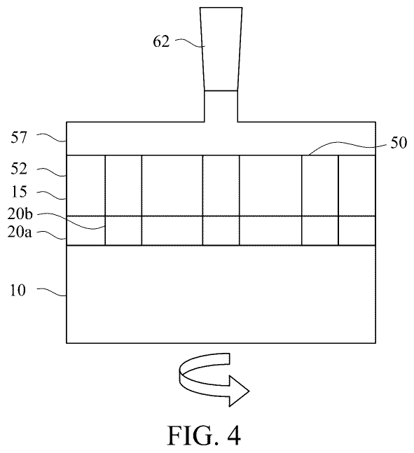

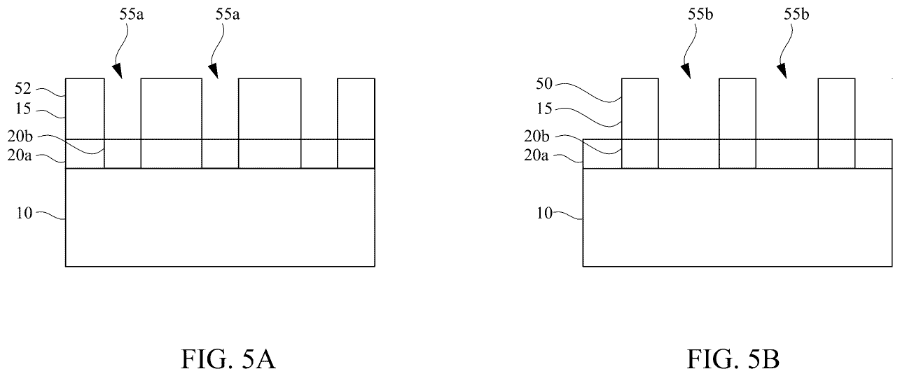

The selectively exposed photoresist layer is subsequently developed by applying a developer to the selectively exposed photoresist layer in operation S170. As shown in FIG. 4, a developer 57 is supplied from a dispenser 62 to the photoresist layer 15. In some embodiments, the exposed region 50 of the photoresist is removed by the development operation S170, as shown in FIG. 5A to form a pattern of openings 55a in the photoresist layer exposing portions of the resist underlayer 20b that were exposed to the actinic radiation. In other embodiments, the unexposed region 52 of the photoresist layer is removed by the developer 57 forming a pattern of openings 55b in the photoresist layer 15 exposing portions of the resist underlayer 20a, as shown in FIG. 5B. In some embodiments, portions of the resist underlayer 20 exposed to the developer 57 are removed by the developer 57 during the development operation S170.

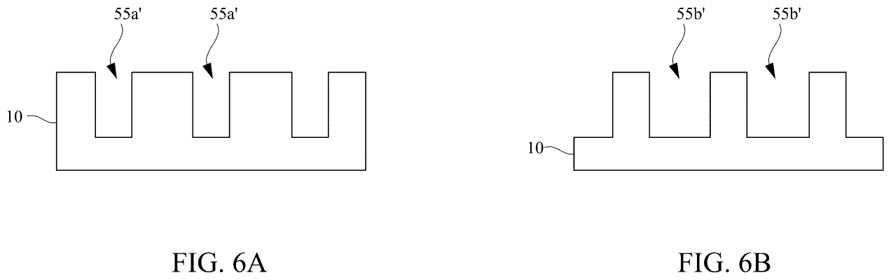

In some embodiments, the pattern of openings 55a, 55b in the photoresist layer 15 is extended through the resist underlayer 20 into the substrate 10 to create a pattern of openings 55a′, 55b′ in the substrate 10, thereby transferring the pattern in the photoresist layer 15 into the substrate 10, as shown in FIGS. 6A and 6B. The pattern is extended into the substrate by etching, using one or more suitable etchants. In some embodiments, the etching operation removes the portions of the resist underlayer 20a, 20b between the photoresist pattern features 55a, 55b. The photoresist layer pattern 50, 52 is at least partially removed during the etching operation in some embodiments. In other embodiments, the photoresist layer pattern 50, 52 and the remaining portion of the resist underlayer 20a, 20b under the photoresist layer pattern are removed after etching the substrate 10 by using a suitable photoresist stripper solvent or by a photoresist ashing operation.

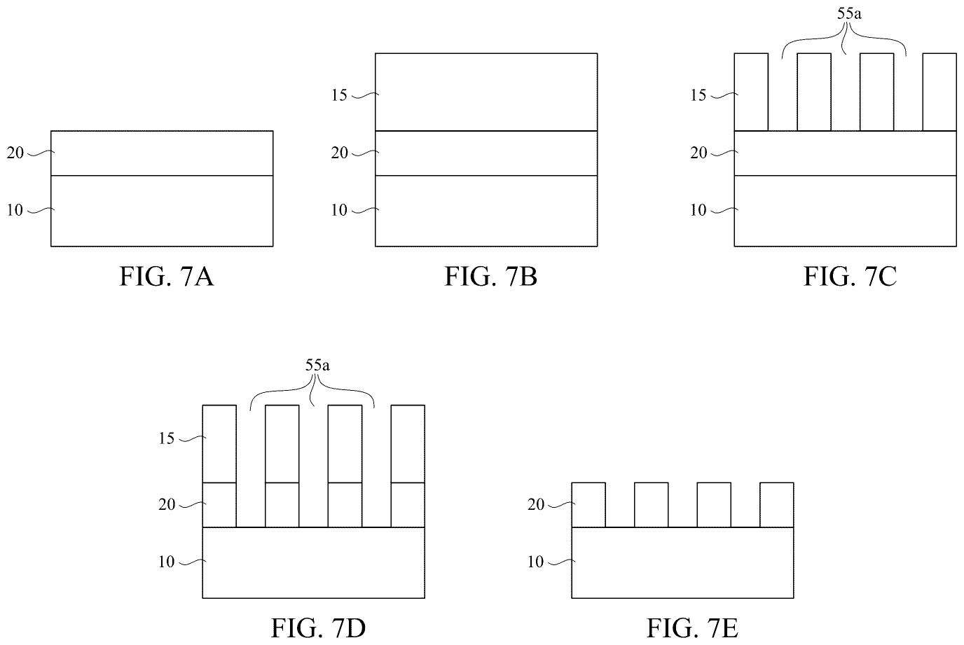

FIGS. 7A, 7B, 7C, 7D, and 7E schematically illustrate a series of operations conducted on a substrate 10, according to some embodiments. FIG. 7A illustrates the resist underlayer 20 disposed over the substrate 10. The conditions of forming the resist underlayer 20 can be any suitable conditions disclosed herein in reference to operation S110 in FIG. 1. FIG. 7B illustrates a photoresist layer 15 disposed over the resist underlayer 20. The conditions of forming the photoresist layer 15 can be any suitable conditions disclosed herein in reference to operation S130 in FIG. 1. FIG. 7C illustrates a pattern of openings 55a formed in the photoresist layer 15 after exposure of the photoresist layer to radiation and development of the photoresist layer. The conditions of forming the openings 55a can be any suitable combination of conditions disclosed herein in reference to operations S150, S160, and 170 in FIG. 1. FIG. 7D illustrates the pattern of openings 55a extended into the underlayer after development. Any suitable etching process can be used to extend the openings 55a. FIG. 7E illustrates the pattern of openings 55a in the underlayer after removal of the photoresist layer through a stripping process. Any suitable stripping process can be used to remove the photoresist layer.

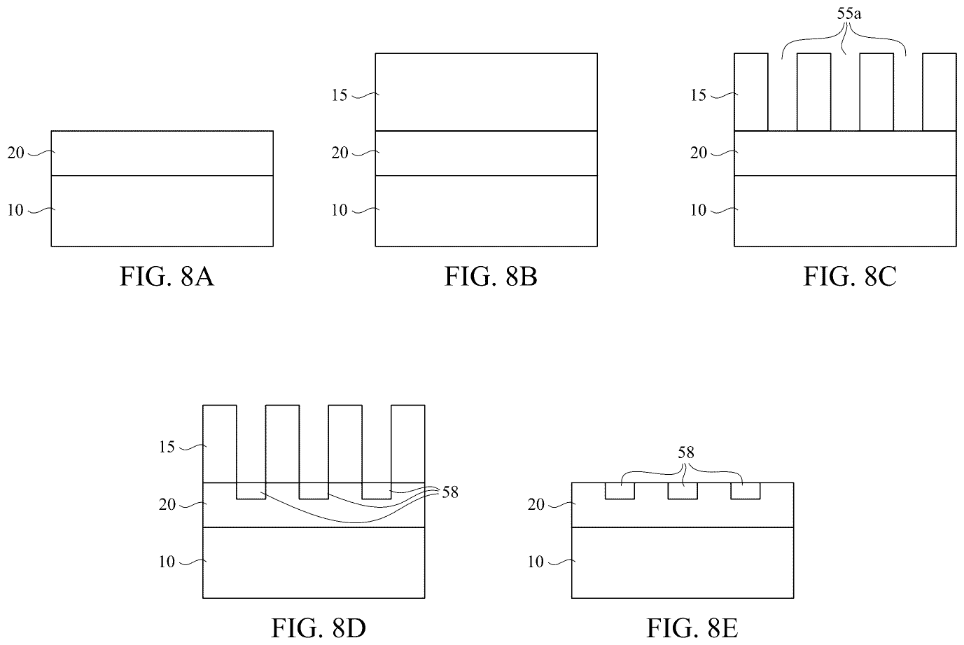

FIGS. 8A, 8B, 8C, 8D, and 8E schematically illustrate a series of operations conducted on a substrate 10, according to some embodiments. FIG. 8A illustrates the resist underlayer 20 disposed over the substrate 10. The conditions of forming the resist underlayer 20 can be any suitable conditions disclosed herein in reference to operation S110 in FIG. 1. FIG. 8B illustrates a photoresist layer 15 disposed over the resist underlayer 20. The conditions of forming the photoresist layer 15 can be any suitable conditions disclosed herein in reference to operation S130 in FIG. 1. FIG. 8C illustrates a pattern of openings 55a formed in the photoresist layer 15 after exposure of the photoresist layer to radiation and development of the photoresist layer. The conditions of forming the openings 55a can be any suitable combination of conditions disclosed herein in reference to operations S150, S160, and 170 in FIG. 1. FIG. 8D illustrates ion-implanted regions 58 formed in the resist underlayer 20. An ion-implantation process is conducted using the patterned photoresist layer 15 as a mask. Ions, such as metal ions, can be directed to the resist underlayer 20 using an ion gun. In some embodiments, an implantation process uses one or more of B, BF₃, As, Sb, and P as implantation species. FIG. 8E illustrates the ion-implanted regions 58 formed in the underlayer 20 after removal of the photoresist layer through a stripping process. Any suitable stripping process can be used to remove the photoresist layer.

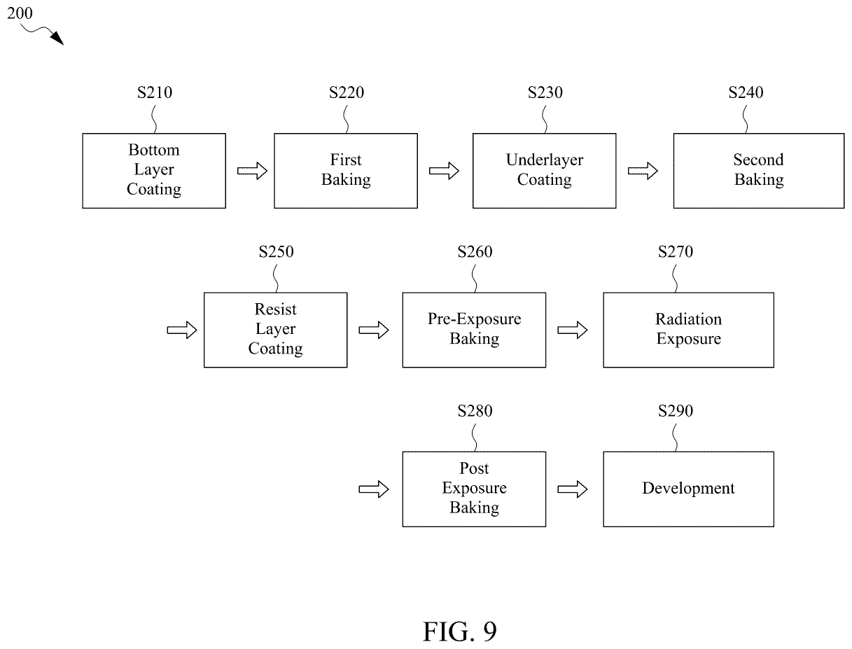

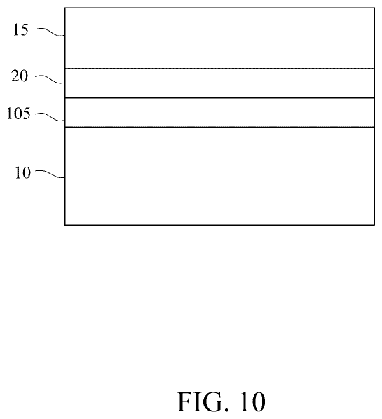

In some embodiments, the resist underlayer 20 is formed over a bottom layer 105 disposed over the substrate 10, as shown in FIGS. 9 and 10. FIG. 9 illustrates a process flow 200 of manufacturing a semiconductor device according to embodiments of the disclosure. In some embodiments, a bottom layer 105 is coated over a substrate in operation S210, as shown in FIG. 10. The bottom layer 105 can be an organic material having a substantially planar upper surface. In some embodiments, the organic material of the bottom layer 105 includes a plurality of monomers or polymers that are not cross-linked. In some embodiments, the bottom layer 105 contains a material that is patternable and/or has a composition tuned to provide anti-reflection properties. Exemplary materials for the bottom layer 105 include carbon backbone polymers. The bottom layer 105 can be used to planarize the structure, as the underlying structure may be uneven depending on the structure of devices in an underlying device layer. In some embodiments, the bottom layer 105 is formed by a spin-coating process. In some embodiments, the bottom layer 105 is made of a spin-on carbon. In certain embodiments, the thickness of the bottom layer 105 ranges from about 50 nm to about 500 nm. The bottom layer is subsequently baked in a first baking operation S220 in some embodiments to evaporate solvents in the bottom layer composition in some embodiments. The bottom layer 105 is baked at a temperature and time sufficient to cure and dry the bottom layer 105. In some embodiments, the bottom layer 105 is heated at a temperature in a range of about 80° C. to about 300° C. for about 10 seconds to about 10 minutes. In some embodiments, the bottom layer is heated at a temperature ranging from about 150° C. to about 250° C. Heating the bottom layer at temperatures below the disclosed ranges may result in insufficient curing, while heating the bottom layer at temperatures greater than the disclosed ranges may result in damage to the bottom layer and the underlying device features.

In operation S230, an underlayer composition is coated over the bottom layer 105 to form a resist underlayer 20. The resist underlayer 20 is formed to any thickness disclosed herein in reference to FIGS. 1 and 2 by any suitable operations disclosed herein reference to FIGS. 1 and 2. The resist underlayer 20 then undergoes a second baking operation S240. The resist underlayer 20 may be baked at any of the baking conditions (e.g.-time and temperature) disclosed herein in reference to operation S120 in FIG. 1 to cure and dry the resist underlayer 20.

A photoresist layer composition is subsequently coated on a surface of the resist underlayer 20 in operation S250, in some embodiments, to form a photoresist layer 15, as shown in FIG. 10. Then the photoresist layer 15 undergoes a third baking operation S260 (or pre-exposure baking operation) to evaporate solvents in the resist composition in some embodiments. The photoresist layer 15 is baked at a temperature and time sufficient to cure and dry the photoresist layer 15, as disclosed herein in reference to operation S140 in FIG. 1. In some embodiments, the photoresist layer composition is coated on the resist underlayer 20 prior to baking the resist underlayer 20, and the photoresist layer 15 and resist underlayer 20 are baked together in a single baking operation to drive off solvents or cure both layers.

After the third (or pre-exposure) baking operation S260 of the photoresist layer 15, the photoresist layer 15 is selectively exposed to actinic radiation 45/97 (see FIGS. 3A and 3B) in operation S270. The photoresist layer 15 is exposed to actinic radiation according to any suitable operation, including those disclosed herein in reference to operation S150 in FIG. 1.

Next, the photoresist layer 15, the resist underlayer 20, and the bottom layer 105 undergo a fourth baking (or post-exposure bake (PEB)) in operation S280. The conditions of the PEB can be any suitable conditions disclosed herein in reference to operation S160 in FIG. 1

The selectively exposed photoresist layer is subsequently developed by applying a developer to the selectively exposed photoresist layer in operation S290. The development operation may be performed by any suitable techniques, including those disclosed in reference to operation S170 in FIG. 1 and FIG. 4. Additional operations are subsequently performed on the substrate having a patterned photoresist layer to form a patterned substrate as disclosed herein reference to FIGS. 5A, 5B, 6A, and 6B.

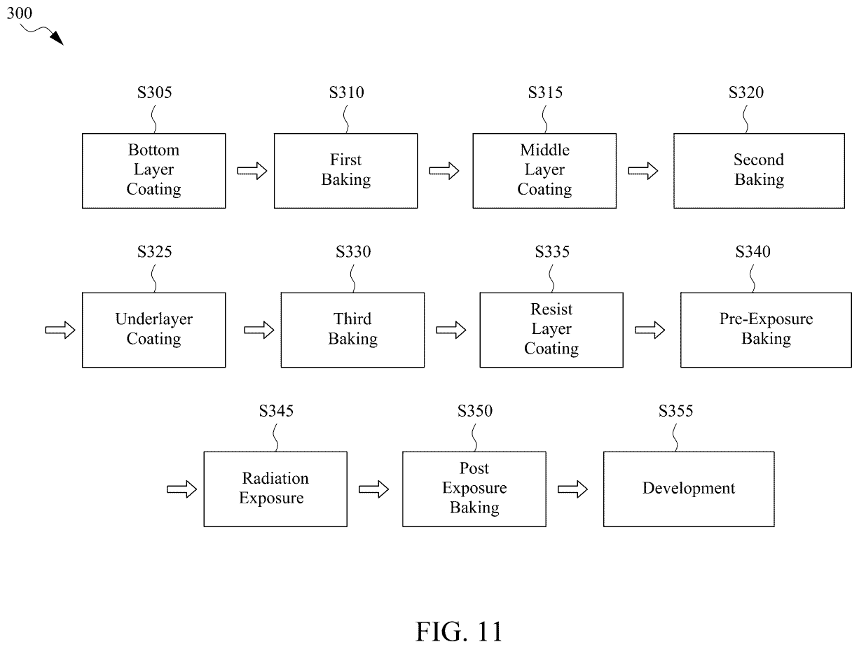

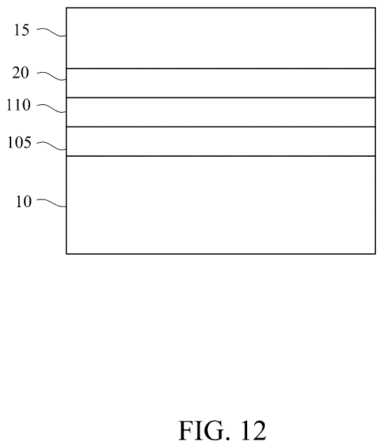

In some embodiments, the resist underlayer 20 is formed over a bottom layer 105 and a middle layer 110 disposed over the substrate 10, as shown in FIGS. 11 and 12. FIG. 11 illustrates a process flow 300 of manufacturing a semiconductor device according to embodiments of the disclosure. In some embodiments, a bottom layer 105 is coated over a substrate in operation S305, as shown in FIG. 12. The bottom layer 105 may be formed by any of the techniques and made of any of the materials disclosed herein in reference to FIGS. 9 and 10. In operation S310, the bottom layer undergoes a first baking operation. The first baking operation may be performed by any suitable technique including the techniques disclosed herein in reference to operation S220 in FIG. 9.

The middle layer 110 is coated over the bottom layer 105 in operation S315. The middle layer 110 may have a composition that provides anti-reflective properties for the photolithography operation and/or hard mask properties. In some embodiments, the middle layer 110 includes a silicon-containing layer (e.g., a silicon hard mask material). The middle layer 110 may include a silicon-containing inorganic polymer. In other embodiments, the middle layer 110 includes a siloxane polymer. In other embodiments, the middle layer 110 includes silicon oxide (e.g., spin-on glass (SOG)), silicon nitride, silicon oxynitride, polycrystalline silicon, a metal-containing organic polymer material that contains metal such as titanium, titanium nitride, aluminum, and/or tantalum; and/or other suitable materials. The middle layer 110 may be bonded to adjacent layers, such as by covalent bonding, hydrogen bonding, or hydrophilic-to-hydrophilic forces.

In some embodiments, the middle layer 110 has a thickness ranging from about 10 nm to about 500 nm. In some embodiments, the thickness of the middle layer 110 ranges from about 20 nm to about 200 nm. In some embodiments, a ratio of the bottom layer thickness to the middle layer thickness ranges from about 1:1 to about 200:1. Middle layer thicknesses less than the disclosed ranges may not provide sufficient adhesion or etching resistance. Middle layer thicknesses greater than the disclosed ranges may be unnecessarily thick and may not provide any additional significant adhesion or etching resistance.

The middle layer 110 undergoes a second baking operation S320 to evaporate solvents or cure the middle layer composition in some embodiments. In some embodiments, the second baking operation S320 causes a silicon-containing monomer to polymerize or silicon-containing polymers to crosslink. In some embodiments, the middle layer 110 is heated at a temperature ranging from about 150° C. to about 300° C. for about 10 seconds to about 10 minutes. In other embodiments, the middle layer 110 is heated at a temperature ranging from about 200° C. to about 250° C. Heating the middle layer at temperatures below the disclosed ranges may result in insufficient curing or crosslinking, while heating the middle layer at temperatures greater than the disclosed ranges may result in damage to the middle layer and the underlying device features.

In operation S325, an underlayer composition is coated over the middle layer 110 to form a resist underlayer 20. The resist underlayer 20 is formed to any thickness disclosed herein in reference to FIGS. 1 and 2 by any suitable operations disclosed herein reference to FIGS. 1 and 2. The resist underlayer 20 then undergoes a third baking operation S330. The resist underlayer 20 may be baked at any of the baking conditions (e.g.-time and temperature) disclosed herein in reference to operation S120 in FIG. 1 to cure and dry the resist underlayer 20.

A photoresist layer composition is subsequently coated on a surface of the resist underlayer 20 in operation S335, in some embodiments, to form a photoresist layer 15, as shown in FIG. 12. Then the photoresist layer 15 undergoes a fourth baking operation S340 (or pre-exposure baking operation) to evaporate solvents in the resist composition in some embodiments. The photoresist layer 15 is baked at a temperature and time sufficient to cure and dry the photoresist layer 15, as disclosed herein in reference to operation S140 in FIG. 1. In some embodiments, the photoresist layer composition is coated on the resist underlayer 20 prior to baking the resist underlayer 20, and the photoresist layer 15 and resist underlayer 20 are baked together in a single baking operation to drive off solvents or cure both layers. In some embodiments, the bottom layer 105, middle layer 110, resist underlayer 20, and the photoresist layer 15 are baked together in a single baking operation to drive off solvents or cure all four layers. In other embodiments, the bottom layer 105 is cured in a first baking operation and then the middle layer 110, resist underlayer 20, and photoresist layer are cured in a second baking operation. In other embodiments, the bottom layer 105 and middle layer 110 are cured in a first baking operation and the resist underlayer 20 and the photoresist layer 15 are cured in a second baking operation. In other embodiments, the bottom layer 110, middle layer 105, and the resist underlayer 20 are cured in a first baking operation and the photoresist layer 15 is cured in a second baking operation.

After the fourth (or pre-exposure) baking operation S340 of the photoresist layer 15, the photoresist layer 15 is selectively exposed to actinic radiation 45/97 (see FIGS. 3A and 3B) in operation S345. The photoresist layer 15 is exposed to actinic radiation according to any suitable operation, including those disclosed herein in reference to operation S150 in FIG. 1.

Next, the photoresist layer 15, the resist underlayer 20, the middle layer 110, and the bottom layer 105 undergo a fifth baking (or post-exposure bake (PEB)) in operation S350. The conditions of the PEB can be any suitable conditions disclosed herein in reference to operation S160 in FIG. 1

The selectively exposed photoresist layer is subsequently developed by applying a developer to the selectively exposed photoresist layer in operation S355. The development operation may be performed by any suitable techniques, including those disclosed in reference to operation S170 in FIG. 1 and FIG. 4. Additional operations are subsequently performed on the substrate having a patterned photoresist layer to form a patterned substrate as disclosed herein in reference to FIGS. 5A, 5B, 6A, and 6B.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXa, where M is a metal and X is N, S, Se, O, Si, and a is from about 0.4 to about 2.5. In some embodiments, the substrate 10 includes one or more of titanium, aluminum, cobalt, ruthenium, titanium nitride, tungsten nitride, and tantalum nitride.

In some embodiments, the substrate 10 includes a dielectric having at least a silicon or metal oxide or nitride of the formula MXb, where Mis a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

In some embodiments, the resist underlayer 20 improves the adhesion of the photoresist layer 15 to the substrate 10. In some embodiments, the resist underlayer 20 functions as a bottom anti-reflective coating (BARC). The BARC absorbs actinic radiation that passes through the photoresist layer, thereby preventing the actinic radiation from reflecting off the substrate or a target layer and exposing unintended portions of the photoresist layer. Thus, the BARC improves line width roughness and line edge roughness of the photoresist pattern.

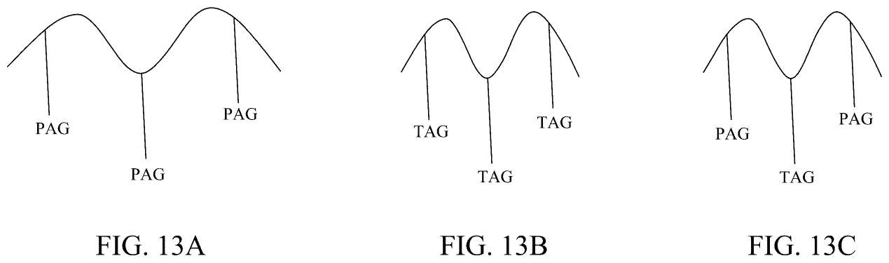

The resist underlayer 20 is made of polymer compositions in some embodiments, wherein the polymer has a polymer main chain (or backbone) with PAG groups, thermal acid generator (TAG) groups, or combinations of PAG and TAG groups. Examples of polymers with pendant PAG and TAG groups are shown in FIGS. 13A, 13B, and 13C. When both PAG and TAG pendant groups are present on the same polymer, a ratio of the number of PAG groups/TAG groups on the polymer ranges from about 99/1 to about 1/99 in some embodiments. In some embodiments, the ratio of the number of PAG groups/TAG groups ranges from about 3/1 to about 1/3. In other embodiments, the ratio of the number of PAG groups/TAG groups ranges from about 3/2 to about 2/3.

In some embodiments, the polymer main chain or backbone included in the resist underlayer composition is an organic polymer or an inorganic polymer. In some embodiments, the polymer main chain is formed from one or more monomers selected from the group consisting of acrylates, acrylic acids, siloxanes, hydroxystyrenes, methacrylates, vinyl esters, maleic esters, methacrylonitriles, and methacrylamides. In some embodiments, the polymer main chain or backbone is a co-polymer formed from a plurality of monomeric and/or oligomeric species. In some embodiments, the resist underlayer composition includes a blend of different polymers.

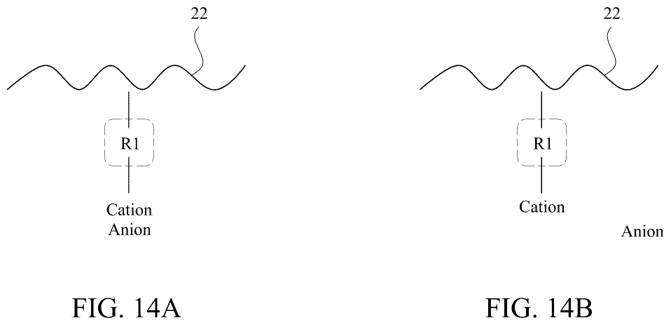

In some embodiments, a PAG group includes an anion moiety and a cationic moiety with an ionic bond existing between the cationic and anionic moieties before the PAG group is exposed to actinic radiation. In some embodiments, the cationic and moieties disassociate upon exposure to actinic radiation. In some embodiments, the polymer includes the cationic moiety covalently bonded to any portion of the polymer or the polymer main chain, and the anionic moiety disassociates from the cationic moiety upon exposure to actinic radiation. In some embodiments, the anionic moieties of the PAG groups are not covalently bonded to the polymer. In some embodiments, the underlayer includes the polymer wherein no anionic moieties of any PAG groups are covalently bonded to the polymer or the polymer main chain. FIG. 14A illustrates an embodiment of a polymer composition of the underlayer including a PAG group including cationic and anionic moieties where the cationic moiety is covalently bonded to the polymer main chain 22 via a linking group R1. FIG. 14B illustrates the polymer composition of FIG. 10A after irradiation of the composition with actinic radiation such that the anionic moiety disassociates from the cationic moiety and the cationic moiety remains covalently bonded to the polymer. In some embodiments, R1 is a unbranched or branched, cyclic or non-cyclic, saturated or unsaturated C1-C30 group such as an alkyl or an alkene group. In some embodiments, R1 is substituted with one or more halogen atoms selected from iodine, chlorine, fluorine, and bromine. In some embodiments R1 includes at least one of —S—; —P—; —P(O₂)—; —C(═O)S—; —C(═O)O—; —O—; —N—; —C(═O)N—; —SO₂O—; —SO₂S—; —SO—, —SO₂—, a carboxylic acid group, an ether group, a ketone group, an ester group, or a phenyl group. The length of the R1 linking group can be tailored to set a diffusion length of the PAG group. The bound cationic moiety can influence the trench area and control the sensitivity of the polymer to which the cationic moiety is bonded.

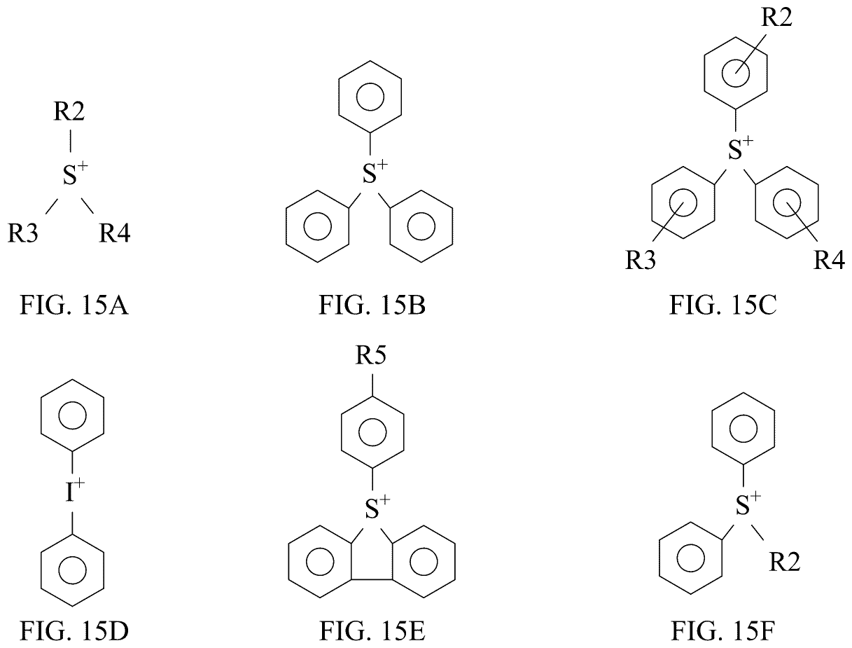

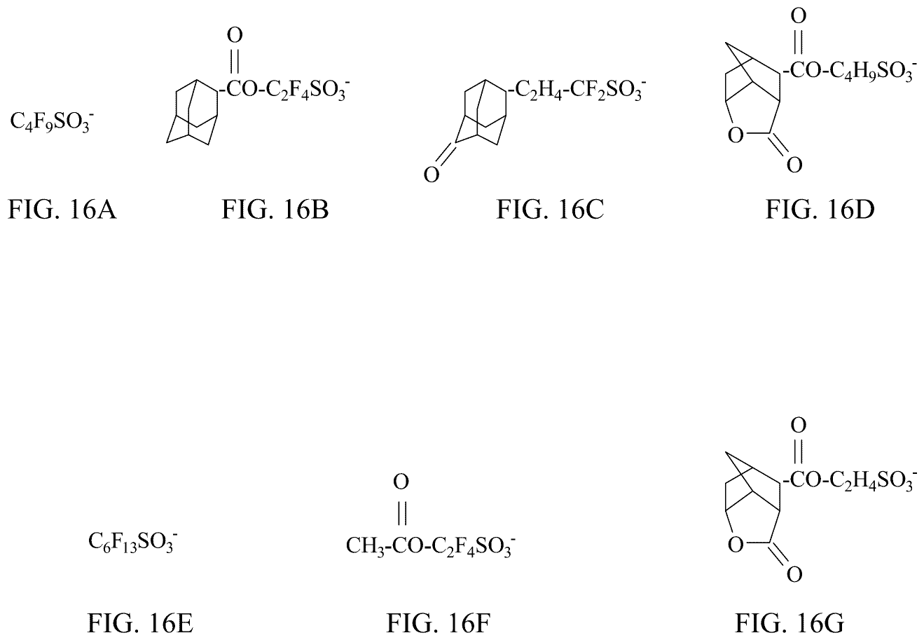

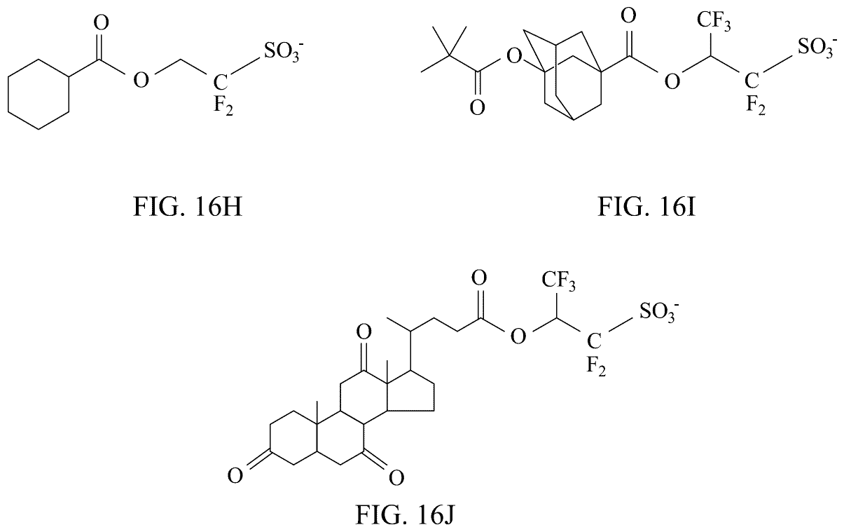

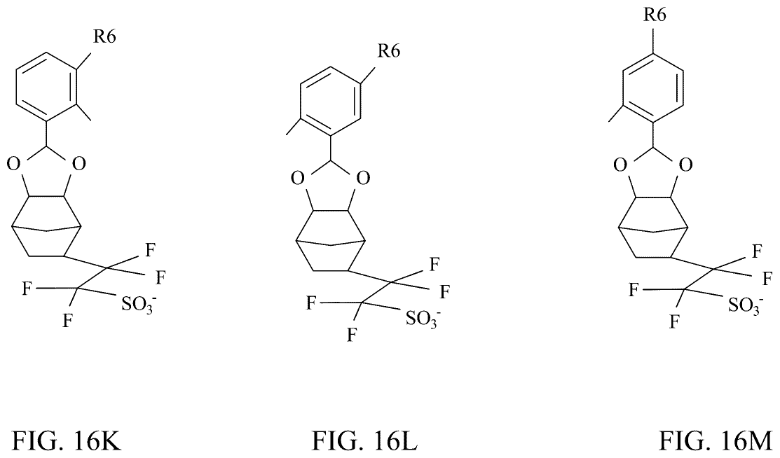

FIGS. 15A, 15B, 15C, 15D, 15E, and 15F illustrate cationic moieties of PAG groups that can be covalently bonded to the polymer in the underlayer composition according to embodiments of the present disclosure, wherein R2, R3, R4, and R5 each independently represent a cyclic or noncyclic, saturated or unsaturated, branched or unbranched C1-C12 group such as an alkyl group or an alkenyl group. FIGS. 16A, 16B, 16C, 16D, 16E, 16F, 16G, 16H, 16I, 16J, 16K, and 16M illustrate anionic moieties of PAG groups that can be ionic bonded to the cationic moieties and dissociate from the cationic moieties upon exposure to actinic radiation, wherein R6 is a cyclic or noncyclic, saturated or unsaturated, substituted or unsubstituted, branched or unbranched C1-C9 group such as an alkyl group or an alkenyl group. In some embodiments, the C1-C9 group is unsubstituted or substituted with one or more selected from a halogen atom (one or more of chlorine, fluorine, bromine, and iodine), —S—, —P—, —P(O₂)—, —C(═O)S—, —C(═O)O—, —O—, —N—, —C(═O)N—, —SO₂O—, —SO₂S—, —SO—, —SO₂—, a carboxyl group, an ether group, a ketone group, an ester group, or an aryl group such as a phenyl group. After radiation exposure and thermal treatment, dissociation of the anionic moiety from the cationic moiety can result in acid diffusion into the photoresist layer to form an acid concentration gradient in a region of the photoresist layer proximal to the resist underlayer.

After post exposure baking, the amount of cationic moieties of PAG groups bonded to the polymer ranges from range from about 0.1 atomic % to about 30 atomic %, or from about 1 atomic % to about 25 atomic % based on the total atomic weight of the polymer

The polymer can include any one or more of the cations and anions in FIGS. 15A-15F and 16A-16M. Any one or more of the cations of FIGS. 15A-15F can be paired with any one or more of the anions of FIGS. 16A-16M or any other suitable anion according to the present disclosure. Likewise, any one or more of the anions of FIGS. 16A-16M can be paired with any one or more of the cations of FIGS. 15A-15F or any other suitable cation. The PAG groups according to this disclosure are not limited to the PAG groups shown in FIGS. 15A-15F and FIGS. 16A-16M.

In some embodiments, the pendant PAG groups are one or more groups selected from the group consisting of a C3-C50 alkyl group containing fluorine atoms with at least one light-sensitive functional group. In some embodiments, the polymer includes one or more PAG groups selected from N-hydroxynaphthalimide triflate, sulfonium salts, triphenylsulfonium triflate, triphenylsulfonium nonaflate, dimethylsulfonium triflate, iodonium salts, diphenyliodonium nonaflate, and norbornene dicarboximidyl nonaflate. The PAG groups may be substituted with epoxy groups, azo groups, alkyl halide groups, imine groups, alkene groups, alkyne groups, peroxide groups, ketone groups, aldehyde groups, allene groups, aromatic groups, or heterocyclic groups. In some embodiments, the aromatic groups are phenyl groups, naphthalenyl groups, phenanthrenyl groups, anthracenyl groups, phenalenyl groups, or other aromatic groups containing one or more three to ten-membered rings.

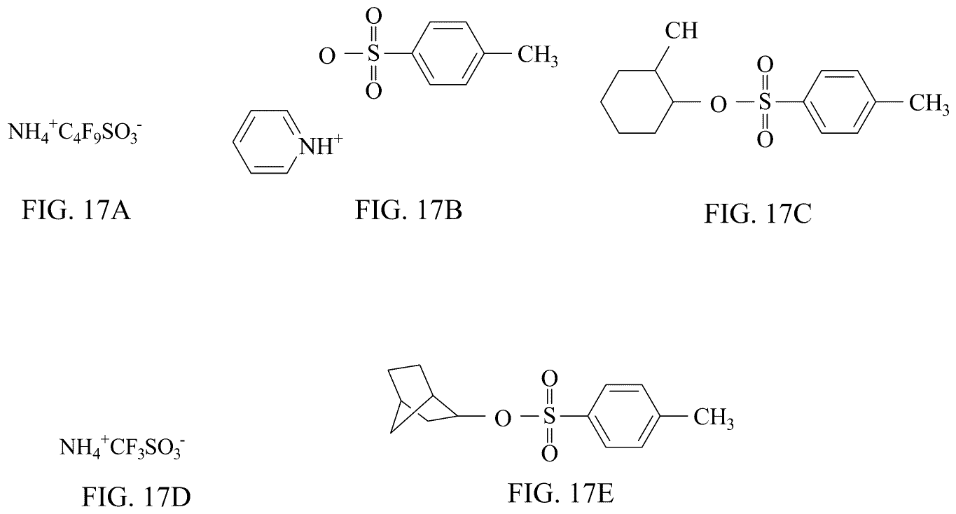

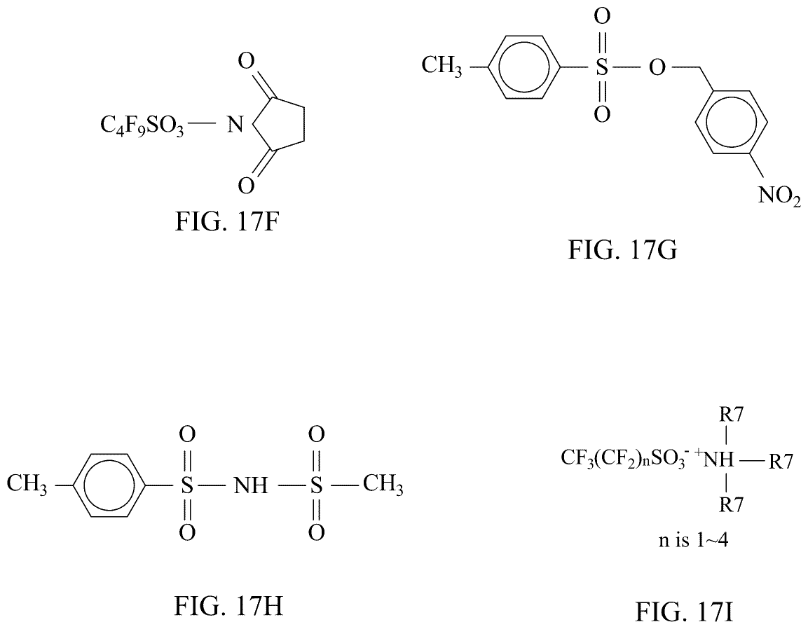

In some embodiments, the resist underlayer includes a composition including one or more of one or more free TAG compounds or one or more TAG groups bonded to a polymer within the composition. A free TAG compound can be free from covalent bonds with any polymer in the resist underlayer. The free TAG compound or TAG groups can generate acid during a baking operation as described herein to cause crosslinking of crosslinking groups in the resist underlayer and possibly generate acid that migrates to the photoresist layer. In some embodiments, the TAG groups are at least one selected from the compounds shown in FIGS. 17A, 17B, 17C, 17D, 17E, 17F, 17G, 17H, and 17I. In FIG. 17I, each R7 is independently a cyclic or noncyclic, saturated or unsaturated, substituted or unsubstituted, branched or unbranched C1-C9 group such as an alkyl or an alkenyl group, and n is 1 to 4. In some embodiments, the C1-C9 group is unsubstituted or substituted with one or more selected from a halogen atom (one or more of chlorine, fluorine, bromine, and iodine), —S—, —P—, —P(O₂)—, —C(═O)S—, —C(═O)O—, —O—, —N—, —C(═O)N—, —SO₂O—, —SO₂S—, —SO—, —SO₂—, a carboxyl group, an ether group, a ketone group, an ester group, or an aryl group such as a phenyl group. In some embodiments, the resist underlayer includes a composition including a polymer including covalently bonded TAG groups, wherein the polymer includes from about 0.1 atomic % to about 30 atomic %, or from about 1 atomic % to about 25 atomic % of the TAG groups based on a total atomic weight of the polymer. Amounts of TAG groups below the above-noted ranges may be insufficient to drive a desired degree of crosslinking, while amounts of TAG groups above the above-noted ranges may deteriorate other desired properties of the resist underlayer or overlying photoresist layer.

In some embodiments, one or more of the PAG group or TAG group includes an element with a high EUV absorption, such as an EUV absorption greater than about 5×10⁵ cm²/gm. In some embodiments, the PAG group or TAG group includes an element selected from the group consisting of F, Cl, Br, I, and combinations thereof.

In some embodiments, one or more of the PAG group or TAG group further includes a sensitizer core, wherein the sensitizer core includes n aromatic rings, where n≤5, and m proton source functional groups, where m≤2n+3. In some embodiments, the proton source functional groups include —OH or —SH. In some embodiments, the sensitizer core is a phenyl group, a naphthalenyl, a phenanthrenthyl group, or an anthracenyl group. In some embodiments, the sensitizer core is one or more selected from the group consisting of 1,3-naphthalenediol, 1-phenanthrenol, and 1,2,3-trihydroxybenzene.

In some embodiments, the underlayer includes PAG groups and no TAG groups. In some embodiments, the underlayer includes both PAG groups and TAG groups. In some embodiments, a total concentration of any PAG and TAG groups in the underlayer is less than about 50 wt. % based on a total weight of the underlayer composition. In some embodiments, a total concentration of any PAG and TAG groups in the polymer composition is less than 50 wt. % based on a total weight of the polymer. In some embodiments, a total concentration of any PAG and TAG groups in the underlayer ranges from about 1 wt. % to about 50 wt. % based on a total weight of the underlayer composition. In other embodiments, a total concentration of any PAG and TAG groups in the underlayer ranges from about 5 wt. % to about 40 wt. % based on a total weight of the underlayer composition. In some embodiments, a higher total concentration of any PAG and TAG groups is greater than about 30 wt. % based on a total weight of the polymer composition. In some embodiments, a lower total concentration of any PAG and TAG groups is less than about 30 wt. % based on a total weight of the polymer composition. In some embodiments, the total concentration of any PAG and TAG groups ranges from about 0.1 at. % to about 30 at. % based on the total amount of the polymer. At concentrations below the disclosed ranges, the underlayer may include an insufficient amount of one or more of PAG and TAG groups to provide the desired effect. At concentrations of the PAG or TAG groups greater than the disclosed ranges, substantial improvement in the photoresist pattern profile may not be obtained.

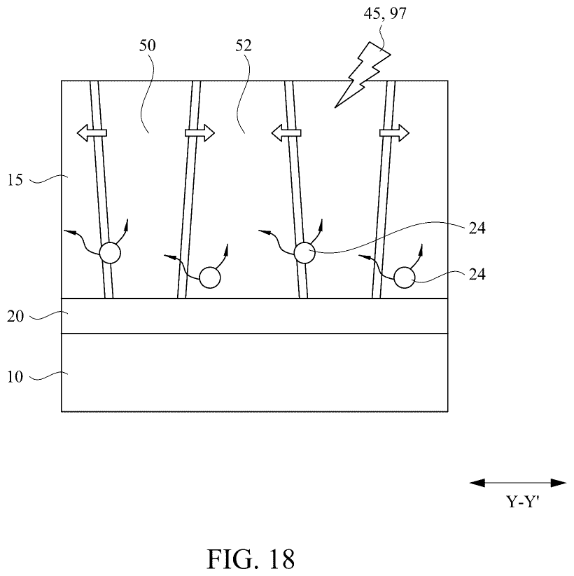

FIG. 18 schematically illustrates an effect of selective actinic radiation exposure of the photoresist layer 15 and the resist underlayer 20 according to some embodiments. The selective exposure to the actinic radiation 45, 97 produces exposed areas 50 and unexposed areas 52 of the photoresist layer 15. The PAG groups in the resist underlayer 20 below the radiation exposed areas 50 are also activated by the actinic radiation 45, 97 that passes through the photoresist layer 15. Because cationic moieties of the PAG groups are bonded to the polymer in the resist underlayer 20, the diffusion length into the photoresist layer 15 is controlled. Upon exposure to actinic radiation, the anionic moieties 24 of the PAG groups dissociate from the cationic moieties and diffuse into the photoresist layer 15. In some embodiments, the anionic moieties drive acid reactions in the photoresist layer. In some embodiments, the acid amplifies crosslinking reactions in the photoresist layer in regions proximal to the resist underlayer 20 thereby increasing the dimensions of bases of the patterned areas 50 of the photoresist layer in directions Y-Y′. This broadening of the exposed areas 50 can reinforce the strength of the patterned photoresist upon development and reduce undercut structures at the bases of the pattern proximal to the resist underlayer. The reactions in the photoresist layer amplified by the anions from the PAG groups can also serve to avoid scum and bridging during a development process. In addition, the bandgap of the PAG is between 5 eV and 10 eV in some embodiments, which can control the sensitivity of the polymer.

In some embodiments in the method illustrated in FIG. 1, the first baking operation S120 activates the TAG group and generates an acid. In other embodiments, the TAG group is activated during any or all of the first baking operation S120, the second baking operation S140, and the third baking operation S160.

In some embodiments in the method illustrated in FIG. 9, the second baking operation S240 activates the TAG group and generates an acid. In other embodiments, the TAG group is activated during any or all of the second baking operation S240, the third baking operation S260, and the fourth baking operation S280.

In some embodiments in the method illustrated in FIG. 11, the third baking operation S330 activates the TAG group and generates an acid. In other embodiments, the TAG group is activated during any or all of the third baking operation, the fourth baking operation S340, and the fifth baking operation S350.

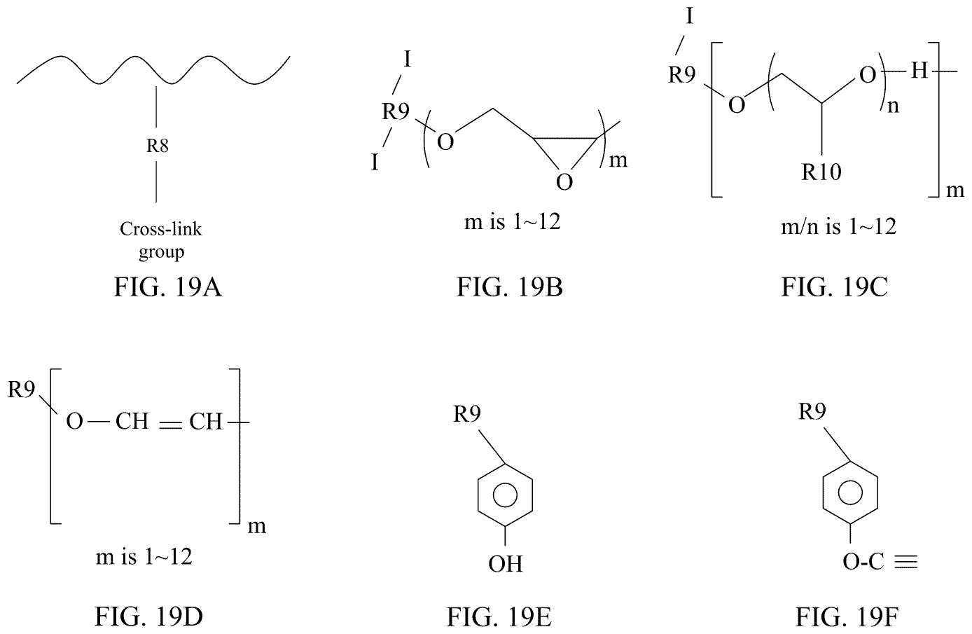

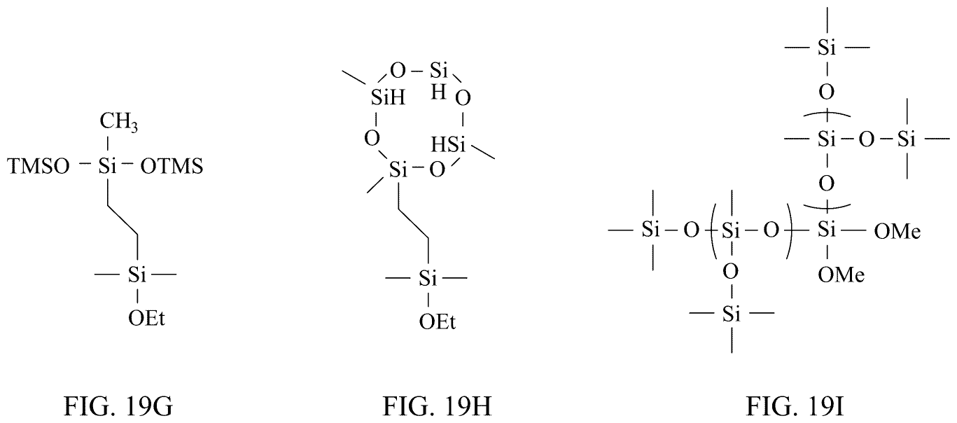

The resist underlayer composition also includes crosslinking groups, in some embodiments. In some embodiments, the crosslinking group is a monomer, oligomer, or polymer including a plurality of epoxy groups, alkenyl groups, alkynyl groups, hydroxy groups, and/or alkoxy groups. A crosslinking group bound to a polymer is illustrated in FIG. 19A, according to an embodiment. In some embodiments, the crosslinking group is bonded to a different polymer than the polymer including the PAG groups and/or the TAG groups. In some embodiments, the polymer including the crosslinking group is formed from one or more monomers selected from the group consisting of acrylates, acrylic acids, siloxanes, hydroxystyrenes, methacrylates, vinyl esters, maleic esters, methacrylonitriles, and methacrylamides. In some embodiments, the number of mer units including crosslinking groups ranges from about 70 wt. % to about 100 wt. %, from about 75 wt. % to about 99 wt. %, or from about 80 wt. % to about 95 wt. % based on the total weight of all mer units in the polymer. By providing a high proportion of crosslinking groups in the resist underlayer, the resist underlayer can be substantially insoluble in solvent-based resist composition disposed over the resist underlayer. In an embodiment, the crosslinking group is bonded to the polymer through a linking group, wherein the linking group R8 as shown in FIG. 19A. In some embodiments, R8 is substituted with at least one of F, Cl, Br, and I. In some embodiments, R8 is a cyclic or noncyclic, saturated or unsaturated, substituted or unsubstituted, branched or unbranched C1-C9 group such as an alkyl or an alkenyl group. In some embodiments, the C1-C9 group is unsubstituted or substituted with one or more selected from a halogen atom (one or more of chlorine, fluorine, bromine, and iodine). In some embodiments, R8 is at least one selected from —S—, —P—, —P(O₂)—, —C(═O)S—, —C(═O)O—, —O—, —N—, —C(═O)N—, —SO₂O—, —SO₂S—, —SO—, —SO₂—, a carboxyl group, a ether group, a ketone group, an ester group, or an aryl group such as a phenyl group In some embodiments, the aryl group is a phenyl group, a naphthalenyl, or an anthracenyl group. In an embodiment, the crosslinking group is at least one selected from the crosslinking groups illustrated in FIGS. 19B, 19C, 19D, 19E, 19F, 19G, 19H, and 19I, where R9 represents any of the linking groups described for R8, and R10 is a C1-C9 cyclic or noncyclic, halogen substituted or unsubstituted, branched or unbranched alkyl or alkenyl group. TMS represents a trimethyl silyl group in FIG. 19G, and Et represents an ethyl group in FIGS. 19G and 19H, and Me represents a methyl group in FIG. 19I. Crosslinking of the resist underlayer can be initiated by the acid generated by the TAG or PAG. In some embodiments, the crosslinking groups are about 30 wt. % to about 70 wt. % of the polymer having the crosslinking groups. When the amount of the crosslinking groups is outside the disclosed ranges there may not be an improvement in the line-width roughness and scum reduction.

In some embodiments, the underlayer composition includes a quencher, which inhibits diffusion of the generated acids. The quencher improves the resist pattern configuration as well as the stability of the photoresist over time. In an embodiment, the quencher is an amine, such as a second lower aliphatic amine, or a tertiary lower aliphatic amine. Specific examples of amines include one or more of trimethylamine, diethylamine, triethylamine, di-n-propylamine, tri-n-propylamine, tripentylamine, diethanolamine, and triethanolamine, and alkanolamine.

In some embodiments, an additive, such as a surfactant, is added to the resist underlayer polymer composition. In some embodiments, the surfactants include nonionic surfactants, polymers having fluorinated aliphatic groups, surfactants that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, and polyoxyethylene sorbitan fatty acid esters.

Specific examples of materials used as surfactants in some embodiments include one or more of polyoxyethylene lauryl ether, polyoxyethylene stearyl ether, polyoxyethylene cetyl ether, polyoxyethylene oleyl ether, polyoxyethylene octyl phenol ether, polyoxyethylene nonyl phenol ether, sorbitan monolaurate, sorbitan monopalmitate, sorbitan monostearate, sorbitan monooleate, sorbitan trioleate, sorbitan tristearate, polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, polyethylene glycol distearate, polyethylene glycol dilaurate, polyethylene glycol, polypropylene glycol, polyoxyethylenestearyl ether, fluorine containing cationic surfactants, fluorine containing nonionic surfactants, fluorine containing anionic surfactants, cationic surfactants, and anionic surfactants.

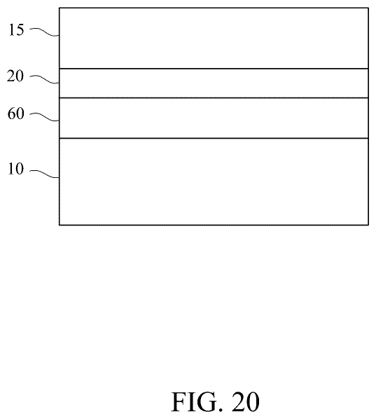

In some embodiments, the resist underlayer 20 is formed by preparing an underlayer coating composition of any of the polymer composition components disclosed herein provided in a solvent. The solvent can be any suitable solvent for dissolving the polymer and the selected components of the compositions. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK). The underlayer coating composition is applied over a substrate 10, a bottom layer 105, a middle layer 110, or a target layer 60 (see FIG. 20). In some embodiments of forming an underlayer coating composition including a solvent, the composition is applied by spin coating. Then the underlayer composition is baked to dry and cure the underlayer 20, as explained herein in reference to FIG. 1.

In various embodiments, the thickness of the resist underlayer 20 ranges from about 5 Å to about 500 Å, from about 20 Å to about 300 Å, and about 100 Å to about 200 Å. Resist underlayer thicknesses less than the disclosed ranges may be insufficient to provide adequate scum reduction, photoresist adhesion, LWR improvement, and anti-reflective properties. Resist underlayer thicknesses greater than the disclosed ranges may be unnecessarily thick and may not provide further improvement in photoresist layer adhesion, LWR improvement, and scum reduction.

In some embodiments, the photoresist layer 15 is a photosensitive layer that is patterned by exposure to actinic radiation. Typically, the chemical properties of the photoresist regions struck by incident radiation change in a manner that depends on the type of photoresist used. Photoresist layers 15 can be either positive tone resists or negative tone resists. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation. In some embodiments, the photoresist layer 15 is a negative tone metallic photoresist that undergoes a cross-linking reaction upon exposure to the radiation.

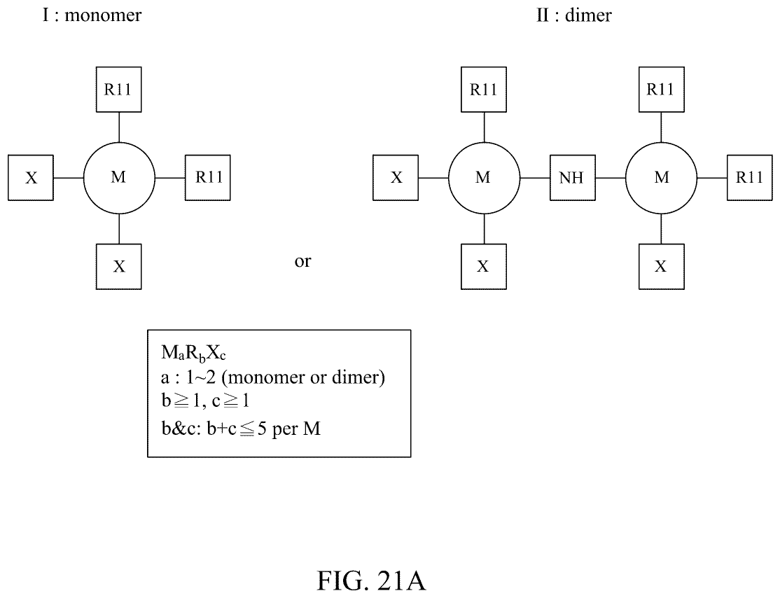

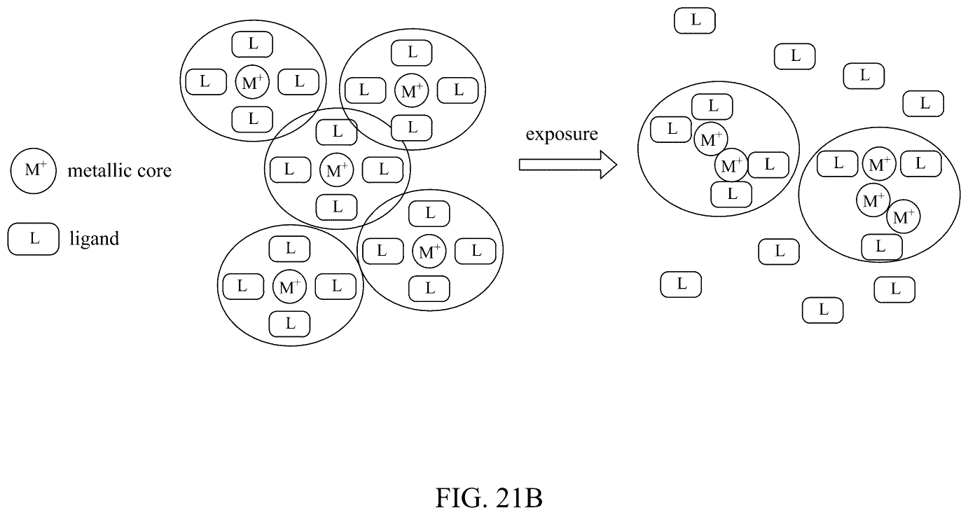

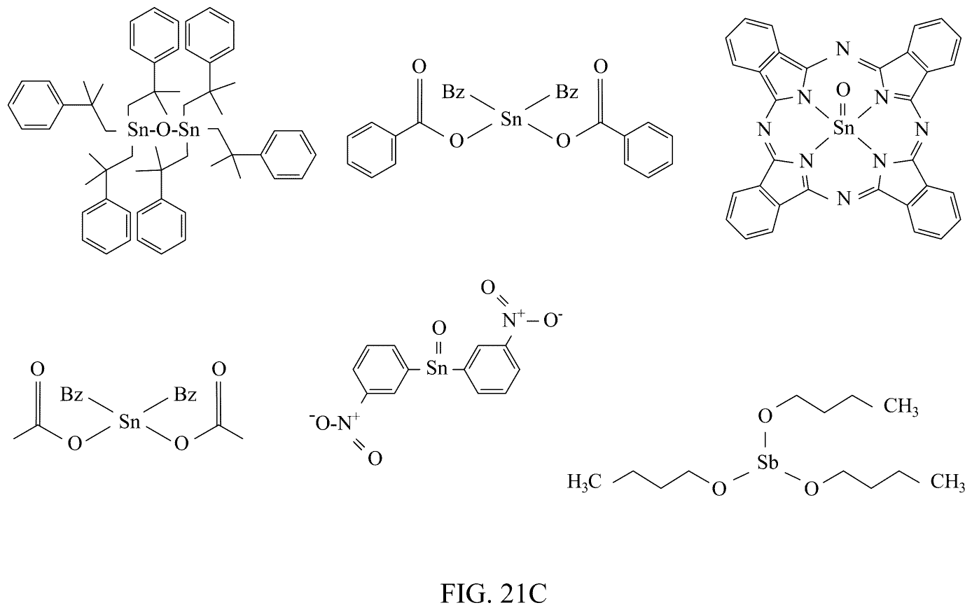

In some embodiments, the photoresist layer 15 is made of a metallic photoresist composition, including a first compound or a first precursor and a second compound or a second precursor combined in a vapor state. The first precursor or first compound is an organometallic having a formula: MₐR_{b}X_{c}, as shown in FIG. 21A, where M is at least one of Sn, Bi, Sb, In, Te, Ti, Zr, Hf, V, Co, Sc, Mo, W, Al, Ga, Si, Ge, P, As, Y, La, Ce, or Lu; and R is a substituted or unsubstituted alkyl, alkenyl, or carboxylate group. In some embodiments, M is selected from the group consisting of Sn, W, Zn, Zr, Bi, Sc and combinations thereof. In some embodiments, R11 is a C3-C6 alkyl, alkenyl, or carboxylate. In some embodiments, each R11 is selected from the group consisting of propyl, isopropyl, butyl, iso-butyl, sec-butyl, tert-butyl, pentyl, isopentyl, sec-pentyl, tert-pentyl, hexyl, iso-hexyl, sec-hexyl, tert-hexyl, and combinations thereof. In some embodiments, X is a ligand, ion, or other moiety, which is reactive with the second compound or second precursor. In some embodiments, 1≤a≤2, b≥1, c≥1, and b+c≤5. In some embodiments, the alkyl, alkenyl, or carboxylate group is substituted with one or more fluoro groups. In some embodiments, the organometallic precursor is a dimer, as shown in FIG. 21A, where each monomer unit is linked by an amine group, and each monomer has a formula: MₐR_{b}X_{c}, as defined above.

In some embodiments, R11 is alkyl, such as CnH2n+1 where n≥3. In some embodiments, R11 is fluorinated, e.g., having the formula CnFxH((2n+1)−x). In some embodiments, R11 has at least one beta-hydrogen or beta-fluorine. In some embodiments, R11 is selected from the group consisting of i-propyl, n-propyl, t-butyl, i-butyl, n-butyl, sec-butyl, n-pentyl, i-pentyl, t-pentyl, and sec-pentyl, and combinations thereof.

In some embodiments, X is any moiety readily displaced by the second compound or second precursor to generate an M-OH moiety, such as a moiety selected from the group consisting of amines, including dialkylamino and monoalkylamino; alkoxy; carboxylates, halogens, and sulfonates. In some embodiments, the sulfonate group is substituted with one or more amine groups. In some embodiments, the halogen is one or more selected from the group consisting of F, Cl, Br, and I. In some embodiments, the sulfonate group includes a substituted or unsubstituted C1-C3 group.

In some embodiments, the first organometallic compound or first organometallic precursor includes a metallic core M+ with ligands L attached to the metallic core M+, as shown in FIG. 21B. In some embodiments, the metallic core M+ is a metal oxide. The ligands L include C3-C12 aliphatic or aromatic groups in some embodiments. The aliphatic or aromatic groups may be unbranched or branched with cyclic, or noncyclic saturated pendant groups containing 1-9 carbons, including alkyl groups, alkenyl groups, and phenyl groups. The branched groups may be further substituted with oxygen or halogen. In some embodiments, the C3-C12 aliphatic or aromatic groups include heterocyclic groups. In some embodiments, the C3-C12 aliphatic or aromatic groups are attached to the metal by an ether or ester linkage. In some embodiments, the C3-C12 aliphatic or aromatic groups include nitrite and sulfonate substituents.

In some embodiments, the organometallic precursor or organometallic compound include any one or more of sec-hexyl tris(dimethylamino) tin, t-hexyl tris(dimethylamino) tin, i-hexyl tris(dimethylamino) tin, n-hexyl tris(dimethylamino) tin, sec-pentyl tris(dimethylamino) tin, t-pentyl tris(dimethylamino) tin, i-pentyl tris(dimethylamino) tin, n-pentyl tris(dimethylamino) tin, sec-butyl tris(dimethylamino) tin, t-butyl tris(dimethylamino) tin, i-butyl tris(dimethylamino) tin, n-butyl tris(dimethylamino) tin, sec-butyl tris(dimethylamino) tin, i-propyl (tris) dimethylamino tin, n-propyl tris(diethylamino) tin, and analogous alkyl (tris) (t-butoxy) tin compounds, including sec-hexyl tris(t-butoxy) tin, t-hexyl tris(t-butoxy) tin, i-hexyl tris(t-butoxy) tin, n-hexyl tris(t-butoxy) tin, sec-pentyl tris(t-butoxy) tin, t-pentyl tris(t-butoxy) tin, i-pentyl tris(t-butoxy) tin, n-pentyl tris(t-butoxy) tin, t-butyl tris(t-butoxy) tin, i-butyl tris(butoxy) tin, n-butyl tris(butoxy) tin, sec-butyl tris(butoxy) tin, i-propyl tris(dimethylamino) tin, or n-propyl tris(butoxy) tin. In some embodiments, the organometallic precursors or organometallic compounds are fluorinated. In some embodiments, the organometallic precursors or compounds have a boiling point less than about 200° C.

In some embodiments, the first compound or first precursor includes one or more unsaturated bonds that can be coordinated with a functional group, such as a hydroxyl group, on the surface of the substrate or an intervening underlayer to improve adhesion of the photoresist layer to the substrate or underlayer.

In some embodiments, the second precursor or second compound is at least one of an amine, a borane, a phosphine, or water. In some embodiments, the amine has a formula NpHnXm, where 0≤n≤3, 0≤m≤3, n+m=3 when p is 1, and n+m=4 when p is 2, and each X is independently a halogen selected from the group consisting of F, Cl, Br, and I. In some embodiments, the borane has a formula BpHnXm, where 0≤n≤3, 0≤m≤3, n+m=3 when p is 1, and n+m=4 when p is 2, and each X is independently a halogen selected from the group consisting of F, Cl, Br, and I. In some embodiments, the phosphine has a formula PpHnXm, where 0≤n≤3, 0≤m≤3, n+m=3, when p is 1, or n+m=4 when p is 2, and each X is independently a halogen selected from the group consisting of F, Cl, Br, and I.

FIG. 21B shows metallic precursors undergoing a reaction as a result of exposure to actinic radiation in some embodiments. As a result of exposure to the actinic radiation, ligand groups L are split off from the metallic core M+ of the metallic precursors, and two or more metallic precursor cores bond with each other.

FIG. 21C shows examples of organometallic precursors according to embodiments of the disclosure. In FIG. 21C, Bz is a benzene group.

In some embodiments, the operations S130, S250, S335 of depositing a photoresist composition is performed by a vapor phase deposition operation. In some embodiments, the vapor phase deposition operation includes atomic layer deposition (ALD) and chemical vapor deposition (CVD). In some embodiments, the ALD includes plasma-enhanced atomic layer deposition (PE-ALD); the CVD includes plasma-enhanced chemical vapor deposition (PE-CVD), metal-organic chemical vapor deposition (MO-CVD), atmospheric pressure chemical vapor deposition (AP-CVD), and low pressure chemical vapor deposition (LP-CVD).

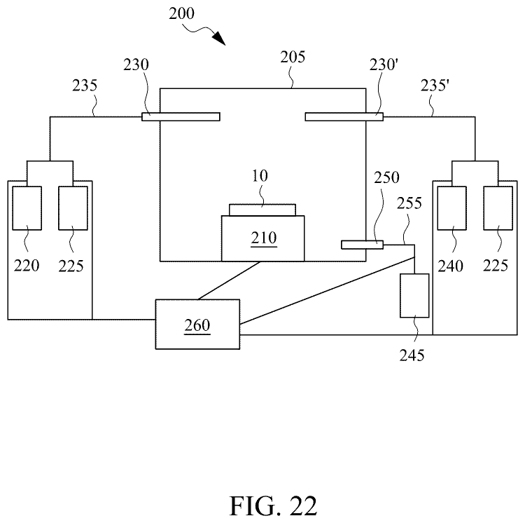

A photoresist layer deposition apparatus 200 according to some embodiments of the disclosure is shown in FIG. 22. In some embodiments, the deposition apparatus 200 is an ALD or CVD apparatus. The deposition apparatus 200 includes a vacuum chamber 205. A substrate support stage 210 in the vacuum chamber 205 supports a substrate 10, such as silicon wafer. In some embodiments, the substrate support stage 210 includes a heater. A first precursor or compound gas supply 220 and carrier/purge gas supply 225 are connected to an inlet 230 in the chamber via a gas line 235, and a second precursor or compound gas supply 240 and carrier/purge gas supply 225 are connected to another inlet 230′ in the chamber via another gas line 235′ in some embodiments. The chamber is evacuated, and excess reactants and reaction byproducts are removed by a vacuum pump 245 via an outlet 250 and exhaust line 255. In some embodiments, the flow rate or pulses of precursor gases and carrier/purge gases, evacuation of excess reactants and reaction byproducts, pressure inside the vacuum chamber 205, and temperature of the vacuum chamber 205 or wafer support stage 210 are controlled by a controller 260 configured to control each of these parameters.

Depositing a photoresist layer includes combining the first compound or first precursor and the second compound or second precursor in a vapor state to form the photoresist composition in some embodiments. In some embodiments, the first compound or first precursor and the second compound or second precursor of the photoresist composition are introduced into the deposition chamber 205 (CVD chamber) at about the same time via the inlets 230, 230′. In some embodiments, the first compound or first precursor and second compound or second precursor are introduced into the deposition chamber 205 (ALD chamber) in an alternating manner via the inlets 230, 230′, i.e.—first one compound or precursor then a second compound or precursor, and then subsequently alternately repeating the introduction of the one compound or precursor followed by the second compound or precursor.

In some embodiments, the deposition chamber temperature ranges from about 30° C. to about 400° C. during the deposition operation, and between about 50° C. to about 250° C. in other embodiments. In some embodiments, the pressure in the deposition chamber ranges from about 5 mTorr to about 100 Torr during the deposition operation, and between about 100 mTorr to about 10 Torr in other embodiments. In some embodiments, the plasma power is less than about 1000 W. In some embodiments, the plasma power ranges from about 100 W to about 900 W. In some embodiments, the flow rate of the first compound or precursor and the second compound or precursor ranges from about 100 sccm to about 1000 sccm. In some embodiments, the ratio of the flow of the organometallic compound precursor to the second compound or precursor ranges from about 1:1 to about 1:5. At operating parameters outside the above-recited ranges, unsatisfactory photoresist layers result in some embodiments. In some embodiments, the photoresist layer formation occurs in a single chamber (a one-pot layer formation). In some embodiments, the resist underlayer 20 is also formed in the same chamber 205 as the photoresist layer 15.

In a CVD process according to some embodiments of the disclosure, two or more gas streams, in separate inlet paths 230, 235 and 230′, 235′, of an organometallic precursor and a second precursor are introduced to the deposition chamber 205 of a CVD apparatus, where they mix and react in the gas phase, to form a reaction product. The streams are introduced using separate injection inlets 230, 230′ or a dual-plenum showerhead in some embodiments. The deposition apparatus is configured so that the streams of organometallic precursor and second precursor are mixed in the chamber, allowing the organometallic precursor and second precursor to react to form a reaction product. Without limiting the mechanism, function, or utility of the disclosure, it is believed that the product from the vapor-phase reaction becomes heavier in molecular weight, and is then condensed or otherwise deposited onto the substrate 10.

In some embodiments, an ALD process is used to deposit the photoresist layer. During ALD, a layer is grown on a substrate 10 by exposing the surface of the substrate to alternate gaseous compounds (or precursors). In contrast to CVD, the precursors are introduced as a series of sequential, non-overlapping pulses. In each of these pulses, the precursor molecules react with the surface in a self-limiting way, so that the reaction terminates once all the reactive sites on the surface are consumed. Consequently, the maximum amount of material deposited on the surface after a single exposure to all of the precursors (a so-called ALD cycle) is determined by the nature of the precursor-surface interaction.

In an embodiment of an ALD process, an organometallic precursor is pulsed to deliver the metal-containing precursor to the substrate 10 surface in a first half reaction. In some embodiments, the organometallic precursor reacts with a suitable underlying species (for example OH or NH functionality on the surface of the substrate) to form a new self-saturating surface. Excess unused reactants and the reaction by-products are removed, by an evacuation-pump down using a vacuum pump 245 and/or by a flowing an inert purge gas in some embodiments. Then, a second precursor, such as ammonia (NH₃), is pulsed to the deposition chamber in some embodiments. The NH₃ reacts with the organometallic precursor on the substrate to obtain a reaction product photoresist on the substrate surface. The second precursor also forms self-saturating bonds with the underlying reactive species to provide another self-limiting and saturating second half reaction. A second purge is performed to remove unused reactants and the reaction by-products in some embodiments. Pulses of the first precursor and second precursor are alternated with intervening purge operations until a desired thickness of the photoresist layer is achieved.

In some embodiments, the photoresist layer 15 is formed to a thickness of about 5 nm to about 50 nm, and to a thickness of about 10 nm to about 30 nm in other embodiments. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the photoresist layer. In some embodiments, each photoresist layer thickness is relatively uniform to facilitate processing. In some embodiments, the variation in thickness of the deposited photoresist layer varies by no more than +25% from the average thickness, in other embodiments each photoresist layer thickness varies by no more than +10% from the average photoresist layer thickness. In some embodiments, such as high uniformity depositions on larger substrates, the evaluation of the photoresist layer uniformity may be evaluated with a 1 centimeter edge exclusion, i.e., the layer uniformity is not evaluated for portions of the coating within 1 centimeter of the edge. A person of ordinary skill in the art will recognize that additional ranges within the explicit ranges above are contemplated and are within the present disclosure.

In some embodiments, the first and second compounds or precursors are delivered into the deposition chamber 205 with a carrier gas. The carrier gas, a purge gas, a deposition gas, or other process gas may contain nitrogen, hydrogen, argon, neon, helium, or combinations thereof.

In some embodiments, the organometallic compound includes tin, antimony, bismuth, indium, tungsten, zinc, zirconium, scandium, and/or tellurium as the metal component, however, the disclosure is not limited to these metals. In other embodiments, additional suitable metals include titanium, hafnium, vanadium, cobalt, molybdenum, aluminum, gallium, silicon, germanium, phosphorus, arsenic, yttrium, lanthanum, cerium, lutetium, or combinations thereof. The additional metals can be as alternatives to or in addition to the Sn, Sb, Bi, In, W, Zn, Zr, Sc, and/or Te.

The particular metal used may significantly influence the absorption of radiation. Therefore, the metal component can be selected based on the desired radiation and absorption cross section. Tin, antimony, bismuth, tellurium, and indium provide strong absorption of extreme ultraviolet light at 13.5 nm. Hafnium provides good absorption of electron beam and extreme UV radiation. Metal compositions including titanium, vanadium, molybdenum, or tungsten have strong absorption at longer wavelengths, to provide, for example, sensitivity to 248 nm wavelength ultraviolet light.

Some embodiments of the photoresist include one or more photoactive compounds (PACs). The PACs are photoactive components, such as PAGs described herein. The PACs may be positive-acting or negative-acting. In some embodiments in which the PACs are a PAGs, the PACs include any one or more of halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di (arylsulfonyl) hydrazines, nitrobenzyl esters, and the s-triazine derivatives.

Specific examples of PAGs include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate, t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

The resist underlayer composition, the bottom layer composition, and the middle layer composition can be applied onto the layer to be patterned, as shown in FIGS. 2, 10, and 12. Each of the layers may be applied using a process such as a spin-on coating process, a dip coating method, an air-knife coating method, a curtain coating method, a wire-bar coating method, a gravure coating method, a lamination method, an extrusion coating method, CVD, ALD, PVD, combinations of these, or the like. In some embodiments, the resist underlayer is applied by a chemical post treatment. In some embodiments, the resist underlayer can be applied and then subject to ultraviolet radiation or heat to crosslink the resist underlayer. . . . In some embodiments, the resist underlayer 20 is applied over a substrate 10, a bottom layer 105, a middle layer 110, or a target layer 60 (see FIG. 20).

After the resist underlayer 20, photoresist layer 15, and bottom layer 105 and middle layer 110 if present have been applied to the substrate 10 and the various baking operations (S120, S140, S220, S240, S260, S310, S320, S330, S340) are performed as necessary, as discussed herein (see FIGS. 1, 9, and 11), the photoresist layer 15 is selectively exposed to form an exposed region 50 and an unexposed region 52, as discussed herein, and shown in FIGS. 3A and 3B. In some embodiments, the exposure to radiation is carried out by placing the photoresist coated substrate in a photolithography tool. The photolithography tool includes a photomask 30, 65, optics, an exposure radiation source to provide the radiation 45, 97 for exposure, and a movable stage for supporting and moving the substrate under the exposure radiation.

After selective exposure to actinic radiation S150, S270, S345, the photoresist layer subsequently undergo post exposure baking S160, S280, S350 and development S170, S390, S355 as explained herein.

In some embodiments, the developer 57 is applied to the photoresist layer 15 using a spin-on process. In the spin-on process, the developer 57 is applied to the photoresist layer 15 from above the photoresist layer 15 while the photoresist-coated substrate is rotated, as shown in FIG. 4. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. The development operation continues for between about 30 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. In some embodiments, a dry development is performed. All such development operations are included within the scope of the embodiments.

During the development process, the developer 57 dissolves the radiation exposed regions 50 of a positive tone resist or dissolves the radiation-unexposed regions 52 of a negative tone resist, exposing the surface of the resist underlayer 20a, 20b, as shown in FIGS. 5A and 5B. In some embodiments, the underlayer is removed by the developer in the regions where the photoresist is removed by developer. In other embodiments, a residual underlayer exposed during developing is removed in a subsequent etching operation. Embodiments of the present disclosure provide patterns having improved definition than provided by conventional photoresist photolithography.

In some embodiments, a dry developer is applied to the selectively exposed photoresist layer. In some embodiments, the dry developer is a plasma or chemical vapor, and the dry development operation is a plasma etching or chemical etching operation. The dry development uses the differences related to the composition, extent of cross-linking, and film density to selectively remove the desired portions of the resist. In some embodiments, the dry development processes uses either a gentle plasma (high pressure, low power) or a thermal process in a heated vacuum chamber while flowing a dry development chemistry, such as BCl₃, BF₃, or other Lewis Acid in the vapor state. In some embodiments, the BCl₃ removes the unexposed material, leaving behind a pattern of the exposed film that is transferred into the underlying layers by plasma-based etch processes.

In some embodiments, the dry development includes plasma processes, including transformer coupled plasma (TCP), inductively coupled plasma (ICP) or capacitively coupled plasma (CCP). In some embodiments, the plasma process is conducted at a pressure of ranging from about 5 mTorr to a pressure of about 20 mTorr, at a power level from about 250 W to about 1000 W, temperature ranging from about 0° C. to about 300° C., and at flow rate of about 100 to about 1000 sccm, for about 1 to about 3000 seconds.

After the development operation, additional processing is performed while the patterned photoresist layer is in place. For example, an etching operation, using dry or wet etching, is performed in some embodiments, to transfer the pattern of the photoresist layer 15 through the resist underlayer 20 to the underlying substrate 10, forming openings 55a′ and 55b′ as shown in FIGS. 6A and 6B. The resist underlayer 20 and the substrate 10 have a different etch resistance than the photoresist layer 15 in some embodiments. In some embodiments, the etchant is more selective to the resist underlayer 20 and substrate 10 than the photoresist layer 15. In some embodiments, a different etchant or etching parameters is used to etch the resist underlayer 20 than to etch the substrate 10. In some embodiments, the exposed resist underlayer 20 is removed by the same etchant that etches the substrate 10. In other words, the same etching operation is used to etch both the exposed regions of the resist underlayer 20 and then the exposed regions of the substrate 10.

In some embodiments where the resist is a positive tone photoresist, a pendant PAG group and optional pendant TAG group are bound to the polymer in the resist underlayer 20 disposed below the photoresist layer 15. The PAG and TAG groups can be any of the PAG and TAG groups disclosed herein.

The pendant PAG group and optional pendant TAG group are used in the resist underlayer (or bottom layer) to increase the acid amount of the bottom portion of the photoresist layer 15 in some embodiments. The acid generated by the PAG and TAG groups supplements any acid generated in the photoresist layer thereby inhibiting or preventing the formation of bottom scum. When the underlayer polymer does not contain a PAG and TAG groups scum may form in the exposed area.

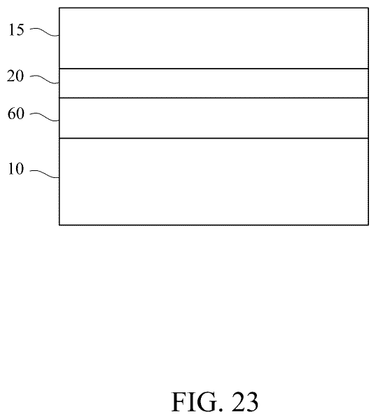

In some embodiments, a target layer 60 to be patterned is disposed over the substrate prior to forming the resist underlayer 20, as shown in FIG. 23. In some embodiments, the target layer 60 is a semiconductor layer; a conductive layer, such as a metallization layer; or a dielectric layer, such as a passivation layer, disposed over a metallization layer. In embodiments where the target layer 60 is a metallization layer, the target layer 60 is formed of a conductive material using metallization processes, and metal deposition techniques, including CVD, ALD, and PVD (sputtering). Likewise, if the target layer 60 is a dielectric layer, the target layer 60 is formed by dielectric layer formation techniques, including thermal oxidation, CVD, ALD, and PVD.

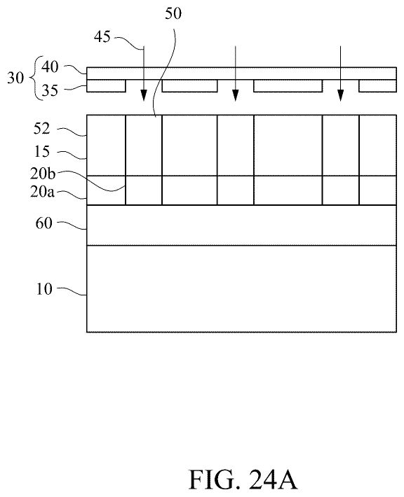

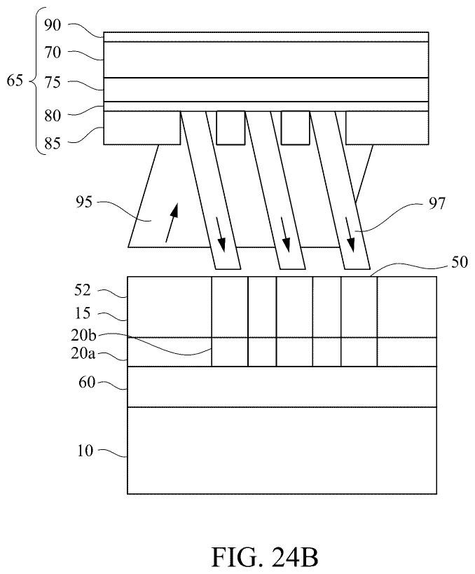

The photoresist layer 15 and resist underlayer 20 are subsequently selectively exposed or patternwise exposed to actinic radiation 45/97 to form exposed regions 50 and 20b and unexposed regions 52 and 20a, in the photoresist layer and resist underlayer, respectively, as shown in FIGS. 24A and 24B, and described herein in relation to FIGS. 3A and 3B.

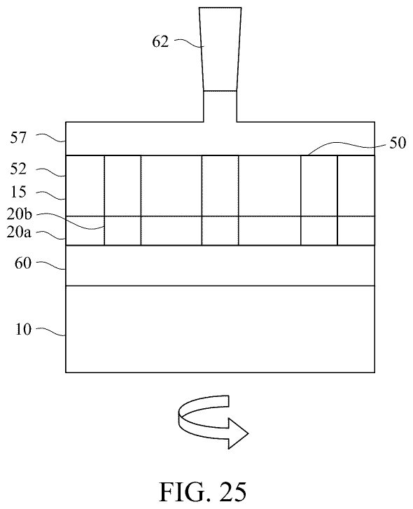

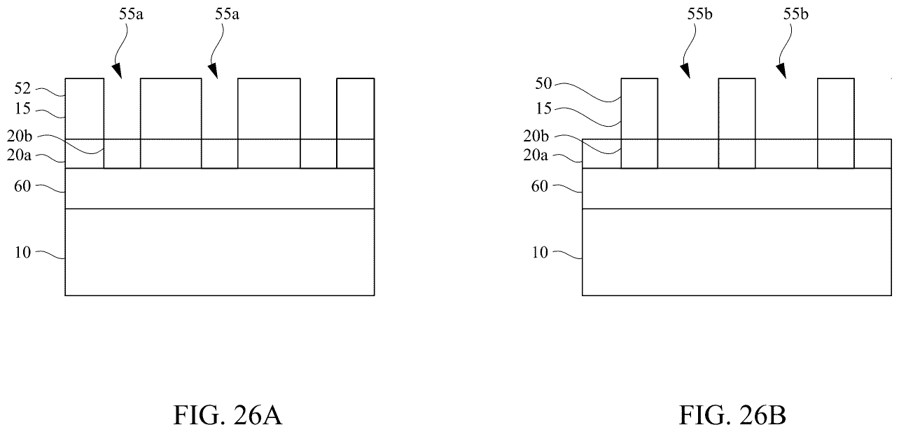

As shown in FIG. 25, the selectively exposed or patternwise exposed photoresist layer 15 is developed by dispensing developer 57 from a dispenser 62 to form a pattern of photoresist openings 55a, 55b, as shown in FIGS. 26A and 26B. FIG. 26A illustrates the development of a positive tone photoresist, and FIG. 26B illustrates the development of a negative tone photoresist. The development operation is similar to that explained with reference to FIGS. 4, 5A, and 5B, herein.

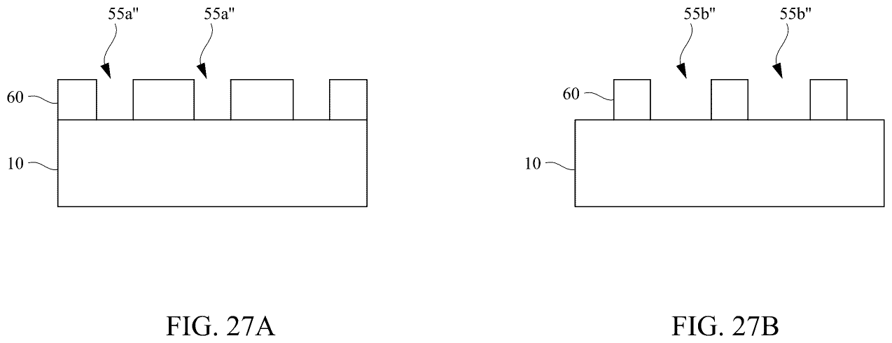

Then, as shown in FIGS. 27A and 27B, the pattern 55a, 55b in the photoresist layer 15 is transferred to the target layer 60 using an etching operation, and the photoresist layer and resist underlayer are removed, as explained with reference to FIGS. 6A and 6B to form pattern 55a″, 55b″ in the target layer 60.

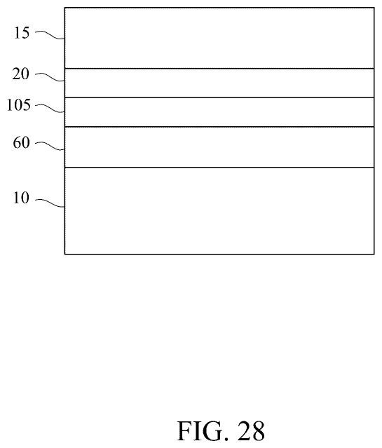

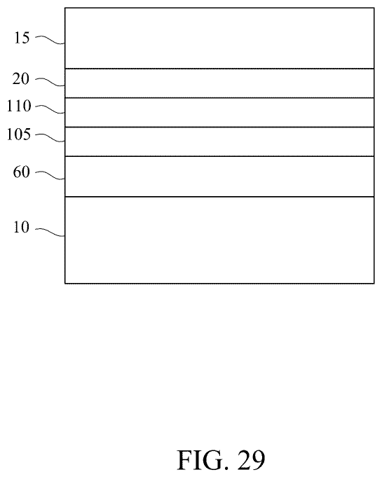

In some embodiments, a bottom layer 105 is formed over the target layer 60 before forming the resist underlayer 20, as shown in FIG. 28. In other embodiments, a bottom layer 105 and a middle layer 110 are formed over the target layer 60 before forming the resist underlayer 20, as shown in FIG. 29. The bottom layer 105 and middle layer 110 can be made of any of the materials and by any of the operations disclosed herein in reference to FIGS. 9 and 11. The structures shown in FIGS. 28 and 29 subsequently undergo the operations disclosed herein in reference to FIGS. 1, 9, and 11.

Other embodiments include other operations before, during, or after the operations described above. In some embodiments, methods disclosed herein are performed over substrates including one or more previously formed semiconductor devices as described herein. In some embodiments, the disclosed methods include forming semiconductor devices, including fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as CMP to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, other memory cells, and combinations thereof are formed, according to embodiments of the disclosure.

Embodiments of the present disclosure improve acid concentration in lower regions of the photoresist layer proximal to an interface with the resist underlayer, thereby reducing scum and bridge formation and improving the thickness of the patterned photoresist layer in regions proximal to the interface the resist underlayer to aid in the reduction of undercut structures in the patterned photoresist layer. In some embodiments, the process window is improved by greater than 5% over conventional techniques. In some embodiments, the exposure dose is reduced by greater than 2% over conventional techniques.

The novel underlayer compositions and semiconductor device manufacturing methods according to the present disclosure provide higher semiconductor device feature resolution and density at higher wafer exposure throughput with reduced defects in a higher efficiency process than conventional exposure techniques. Embodiments of the disclosure provide improved adhesion of the photoresist pattern to the substrate thereby preventing pattern collapse while preventing pattern scum.

According to an embodiment, a method for manufacturing a semiconductor device includes forming a resist underlayer over a substrate, wherein the resist underlayer includes an underlayer composition including a first polymer including pendant photoacid generator (PAG) groups, the PAG groups include cationic moieties ionically bonded to anionic moieties, and the cationic moieties are covalently bonded to the first polymer. The method further includes forming a photoresist layer including a photoresist composition over the resist underlayer; selectively exposing the photoresist layer to actinic radiation; and developing the selectively exposed photoresist layer to form a pattern in the photoresist layer. In an embodiment, the first polymer further includes pendant thermal acid generator (TAG) groups. In an embodiment, the underlayer composition further includes thermal acid generator (TAG) compounds free from covalent bonds with the first polymer. In an embodiment, the first polymer includes no thermal acid generator (TAG) groups. In an embodiment, the anionic moieties of the PAG groups are not covalently bonded to the first polymer. In an embodiment, the first polymer further includes one or more crosslinking groups. In an embodiment, the underlayer composition further includes a second polymer or a monomer, and the one or more crosslinking groups are bonded to the second polymer or the monomer. In an embodiment, the method further includes baking the photoresist layer and the resist underlayer after the selectively exposing the photoresist layer and the resist underlayer. In an embodiment, the baking is conducted at a temperature ranging from 80° C. to 400° C. In an embodiment, the photoresist composition includes an organometallic compound.

According to another embodiment, a method for manufacturing a semiconductor device includes forming a target layer over a substrate; forming a resist underlayer over the target layer, wherein the resist underlayer includes an underlayer composition. The underlayer composition includes a first polymer including pendant photoacid generator (PAG) groups, the PAG groups include cationic moieties covalently bonded to the first polymer, and the first polymer further includes pendant crosslinking groups. The method further includes forming a photoresist layer including a photoresist composition over the resist underlayer, wherein the photoresist composition includes an organometallic compound; and forming a pattern in the photoresist layer and the resist underlayer. In an embodiment, the PAG groups include one or more of an F, Cl, Br, and I. In an embodiment, the first polymer further includes pendant thermal acid generator (TAG) groups. In an embodiment, the TAG groups include one or more of an F, Cl, Br, and I. In an embodiment, no anionic moieties of any of the PAG groups are covalently bonded to the first polymer.

According to another embodiment, a resist underlayer composition includes a polymer including a main chain and photoacid generator (PAG) groups bonded to the main chain, wherein the PAG groups include cationic moieties and anionic moieties, ionic bonds exist between the anionic moieties and the cationic moieties, and covalent bonds exist between the cationic moieties and the main chain; and crosslinking groups bonded to the main chain. In an embodiment, the crosslinking groups are bonded to the main chain through linking groups, and the linking group includes one or more of Cl, Fl, Br, and I. In an embodiment, the anionic moieties of the PAG groups are not covalently bonded to the polymer. In an embodiment, the polymer further includes pendant thermal acid generator (TAG) groups. In an embodiment, the cationic moieties include one or more of:

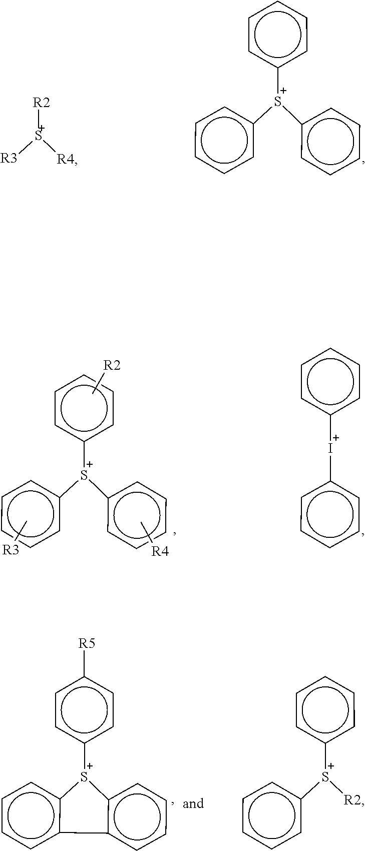

wherein R2, R3, R4, and R5 each independently represent a cyclic or noncyclic, saturated or unsaturated, branched or unbranched C1-C12 group. In an embodiment, the anionic moieties include one or more of:

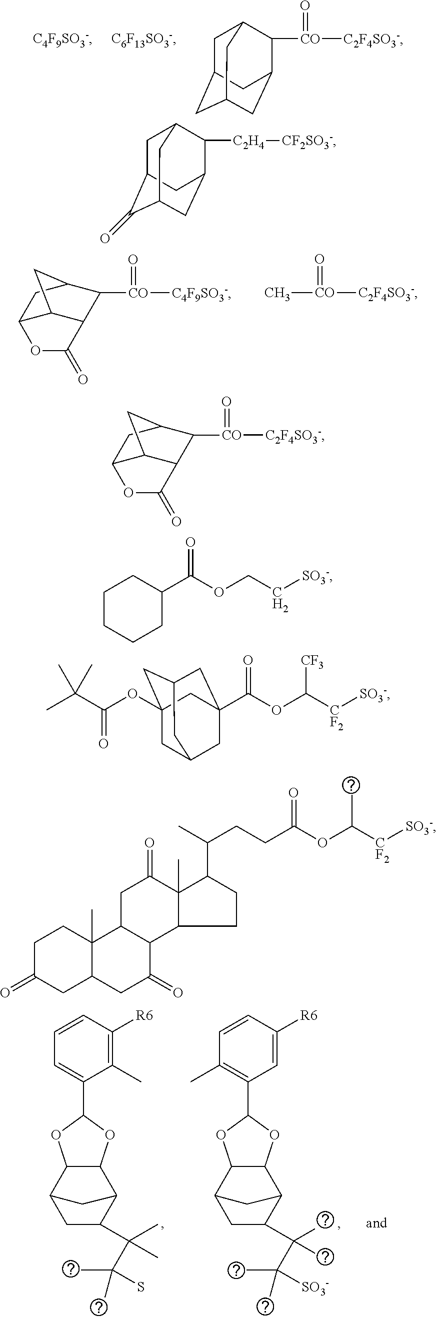

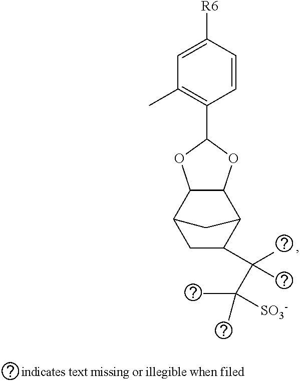

wherein R6 is a cyclic or noncyclic, saturated or unsaturated, substituted or unsubstituted, branched or unbranched C1-C9 group. In an embodiment, the TAG groups include one or more of:

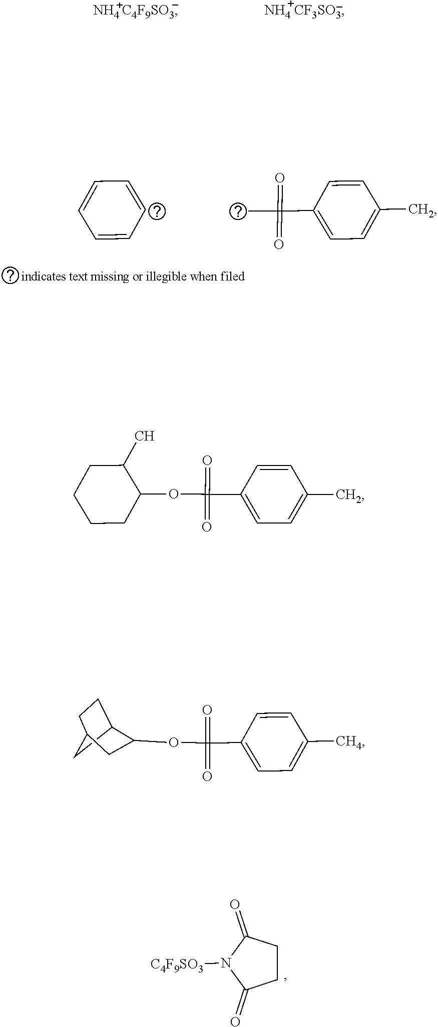

wherein each R7 is independently a cyclic or noncyclic, saturated or unsaturated, substituted or unsubstituted, branched or unbranched C1-C9 group, and n represents 1-4. In an embodiment, the crosslinking groups include one or more of:

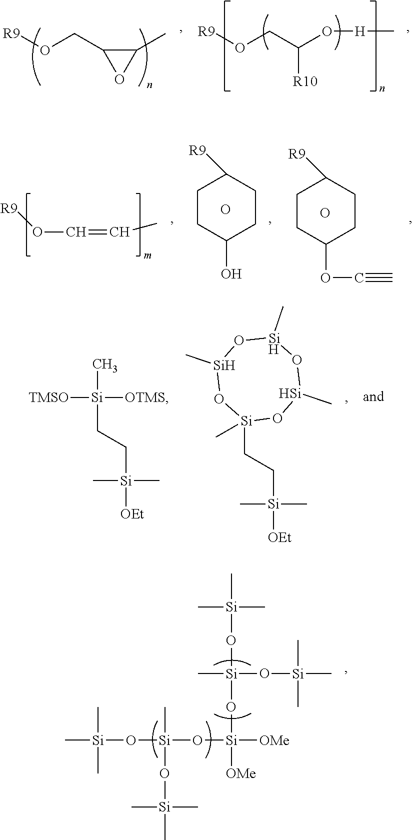

wherein R9 and R10 are each independently a cyclic or noncyclic, saturated or unsaturated, substituted or unsubstituted, branched or unbranched C1-C9 group, TMS represents a trimethyl silyl group, Et represents an ethyl group, and Me represents a methyl group.

According to another embodiment, a method for manufacturing a semiconductor device includes forming a resist underlayer over a substrate, wherein the resist underlayer includes an underlayer composition including a polymer including photoacid generator (PAG) groups, wherein the PAG groups include cationic moieties ionically bonded to anionic moieties, and the cationic moieties are covalently bonded to the polymer; forming a photoresist layer including a photoresist composition over the resist underlayer; selectively exposing the photoresist layer to actinic radiation; after the selectively exposing the photoresist layer to the actinic radiation, baking the photoresist layer, the resist underlayer, and the substrate; and developing the selectively exposed and baked photoresist layer to form a pattern in the photoresist layer. In an embodiment, the cationic moieties include one or more of:

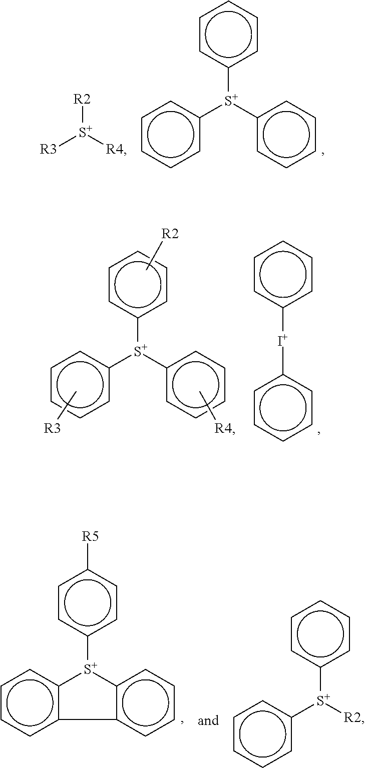

wherein R2, R3, R4, and R5 each independently represent a cyclic or noncyclic, saturated or unsaturated, branched or unbranched C1-C12 group. In an embodiment, the anionic moieties include one or more of:

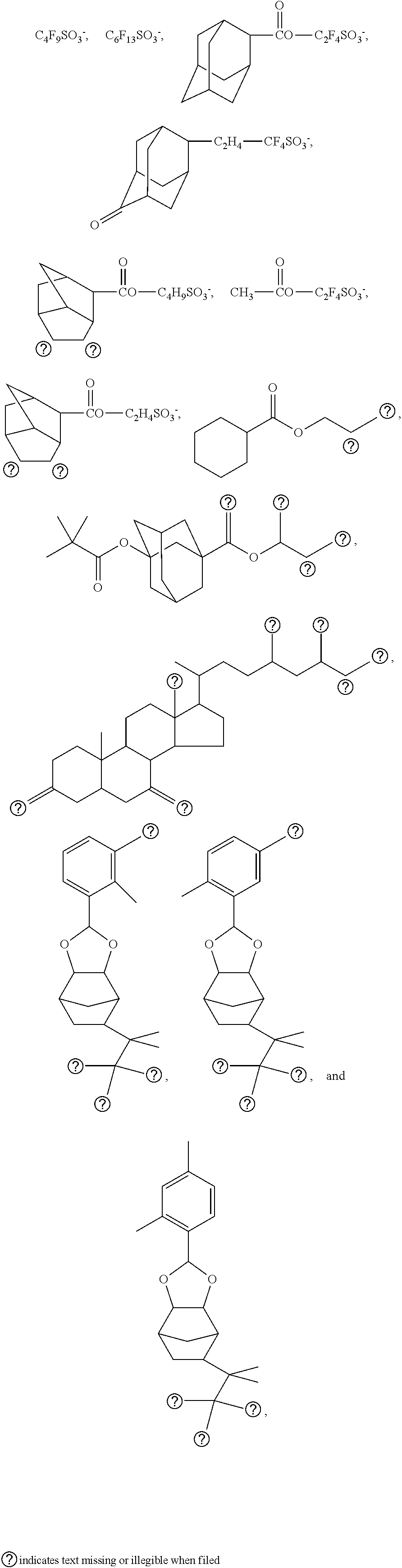

wherein R6 is a cyclic or noncyclic, saturated or unsaturated, substituted or unsubstituted, branched or unbranched C1-C9 group.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a resist underlayer over a substrate, wherein the resist underlayer includes an underlayer composition comprising a first polymer including pendant photoacid generator (PAG) groups, the PAG groups include cationic moieties ionically bonded to anionic moieties, and the cationic moieties are covalently bonded to the first polymer;
forming a photoresist layer comprising a photoresist composition over the resist underlayer;
selectively exposing the photoresist layer to actinic radiation; and
developing the selectively exposed photoresist layer to form a pattern in the photoresist layer.

2. The method according to claim 1, wherein the first polymer further comprises pendant thermal acid generator (TAG) groups.

3. The method according to claim 1, wherein the underlayer composition further comprises thermal acid generator (TAG) compounds free from covalent bonds with the first polymer.

4. The method according to claim 1, wherein the first polymer comprises no thermal acid generator (TAG) groups.

5. The method of claim 1, wherein the anionic moieties of the PAG groups are not covalently bonded to the first polymer.

6. The method of claim 1, wherein the first polymer further comprises one or more crosslinking groups.

7. The method according to claim 6, wherein the underlayer composition further comprises a second polymer or a monomer, and the one or more crosslinking groups are bonded to the second polymer or the monomer.

8. The method according to claim 1, further comprising baking the photoresist layer and the resist underlayer after the selectively exposing the photoresist layer and the resist underlayer.

9. The method according to claim 8, wherein the baking is conducted at a temperature ranging from 80° C. to 400° C.

10. The method according to claim 1, wherein the photoresist composition comprises an organometallic compound.

11. A method for manufacturing a semiconductor device, comprising:
forming a target layer over a substrate;
forming a resist underlayer over the target layer, wherein the resist underlayer includes an underlayer composition, comprising:
a first polymer including:
pendant photoacid generator (PAG) groups, the PAG groups include cationic moieties covalently bonded to the first polymer, and
pendant crosslinking groups;
forming a photoresist layer comprising a photoresist composition over the resist underlayer, wherein the photoresist composition comprises an organometallic compound; and
forming a pattern in the photoresist layer and the resist underlayer.

12. The method according to claim 11, wherein the PAG groups include one or more of an F, Cl, Br, and I.

13. The method according to claim 11, wherein the first polymer further comprises pendant thermal acid generator (TAG) groups.

14. The method according to claim 13, wherein the TAG groups include one or more of an F, Cl, Br, and I.

15. The method according to claim 11, wherein no anionic moieties of any of the PAG groups are covalently bonded to the first polymer.

16. A resist underlayer composition, comprising:
a polymer including a main chain and photoacid generator (PAG) groups bonded to the main chain, wherein the PAG groups include cationic moieties and anionic moieties, ionic bonds exist between the anionic moieties and the cationic moieties, and covalent bonds exist between the cationic moieties and the main chain; and
crosslinking groups bonded to the main chain.

17. The resist underlayer composition according to claim 16, wherein the crosslinking groups are bonded to the main chain through linking groups, and the linking group includes one or more of Cl, Fl, Br, and I.

18. The resist underlayer composition according to claim 16, wherein the anionic moieties of the PAG groups are not covalently bonded to the polymer.

19. The resist underlayer composition according to claim 16, wherein the polymer further comprises pendant thermal acid generator (TAG) groups.

20. The resist underlayer composition according to claim 16, wherein the cationic moieties include one or more of: 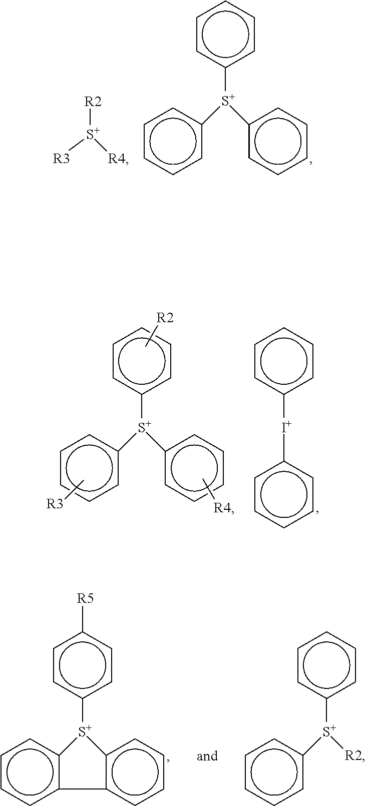
wherein R2, R3, R4, and R5 each independently represent a cyclic or noncyclic, saturated or unsaturated, branched or unbranched C1-C12 group.
